(19) United States
(12) Patent Application Publication
(10) Pub. No.: US 2026/0173657 A1
(43) Pub. Date: Jun. 18, 2026

(54) Display Device

(71) Applicant: LG Display Co., Ltd., Seoul (KR)

(72) Inventors: Jungcheol Shin, Paju-si (KR); YoungWook Lee, Paju-si (KR)

(21) Appl. No.: 19/234,664

(22) Filed: Jun. 11, 2025

(30) Foreign Application Priority Data
Dec. 17, 2024 (KR) 10-2024-0187959

(51) Int. Cl. H10K 59/122; H10K 59/131; H10K 59/80

(52) U.S. Cl. CPC H10K 59/122; H10K 59/131; H10K 59/8792

(57) ABSTRACT

The present disclosure provides a display device including a substrate, an insulating layer disposed on the substrate and including a depression and a peripheral portion surrounding the depression, a first electrode disposed on the depression and the peripheral portion, an auxiliary line spaced apart from the first electrode and disposed on the peripheral portion, a bank covering at least a portion of the first electrode and the auxiliary line and disposed on the peripheral portion, a protection layer disposed on the first electrode and the bank, an intermediate layer disposed on the first electrode and the protection layer, and a second electrode electrically connected to the auxiliary line and disposed on the intermediate layer.

### CROSS REFERENCE TO RELATED APPLICATION

This application claims priority from Republic of Korea Patent Application No. 10-2024-0187959, filed on Dec. 17, 2024, which is hereby incorporated by reference in its entirety.

### TECHNICAL FIELD

The present disclosure relates to electronic devices, and more specifically, to display devices.

### BACKGROUND

In today's information society, display devices for presenting images or visual information to users are increasingly important. The needs for such display devices have caused display technology to be rapidly developed, and various types or usages of display devices have been developed. In addition, as display devices are becoming thinner and lighter, usages of the display devices are increasingly expanding, and displays are widely being applied in various fields of devices, apparatuses, and systems.

Display devices tend to add various functions including functions interoperated or associated with other devices, apparatuses, and systems, as well as stand-alone functions, even when an area occupied by a display area for displaying images is increased.

As the so-called bezel-less or bezel-free designs that make the display area appear full are increasingly becoming popular, recently work has been progressing on reducing an area of a non-display area outside of the display area.

### SUMMARY

To address these issues, one or more embodiments of the present disclosure may provide a display device with improved reliability.

One or more embodiments of the present disclosure may provide a display device that includes a structure where a cathode contact area electrically connecting a common electrode and a common voltage line is disposed in the display area, and is capable of improving luminance unevenness for each area in a display area.

One or more embodiments of the present disclosure may provide a display device that includes a structure where a cathode contact area electrically connecting a common electrode and a common voltage line is disposed in the display area, and is capable of implementing a narrow bezel by reducing a bezel width.

One or more embodiments of the present disclosure may provide a display device that includes a black bank and is capable of improving reflectivity and reflective visibility due to external light.

One or more embodiments of the present disclosure may provide a display device that includes a protection layer between a black bank and a light emitting element and is capable of preventing or at least reducing fume gas caused by the black bank from penetrating into the light emitting element.

According to one or more embodiments of the present disclosure, a display device may be provided that includes a structure capable of improving luminance unevenness and reflectivity and is capable of being driven with low power consumption.

Aspects, examples, and embodiments provided in the present disclosure are not limited to the foregoing description, and additional aspects, examples, and embodiments provided in the present disclosure will become apparent to those skilled in the art from the following description.

According to one or more example embodiments of the present disclosure, a display device can be provided that includes a substrate, an insulating layer disposed on the substrate and including a depression and a peripheral portion surrounding the depression, a first electrode disposed on the depression and the peripheral portion, an auxiliary line spaced apart from the first electrode and disposed on the peripheral portion, a bank covering at least a portion of the first electrode and the auxiliary line and disposed on the peripheral portion, a protection layer disposed on the first electrode and the bank, an intermediate layer disposed on the first electrode and the protection layer, and a second electrode electrically connected to the auxiliary line and disposed on the intermediate layer.

According to one or more example embodiments of the present disclosure, a display device can be provided that includes a substrate including a display area and a non-display area surrounding the display area, an insulating layer located in the display area and including a depression and a peripheral portion, a first electrode disposed on the insulating layer, an auxiliary line spaced from the first electrode and disposed on the peripheral portion, a bank including a first open area corresponding to the depression and a second open area exposing a portion of the auxiliary line, a protection layer disposed on the first electrode located to correspond to an inclined portion of the depression and the bank, an undercut area overlapping with at least a portion of the second open area and disposed under the protection layer, an intermediate layer disposed on the first electrode and the protection layer, and a second electrode electrically connected to the auxiliary line in the undercut area and disposed on the intermediate layer.

According to one or more embodiments of the present disclosure, a display device may be provided with improved reliability.

According to one or more embodiments of the present disclosure, a display device may be provided that includes a structure where a cathode contact area electrically connecting a common electrode and a common voltage line is disposed in the display area, and is capable of improving luminance unevenness for each area in a display area.

According to one or more embodiments of the present disclosure, a display device may be provided that includes a structure where a cathode contact area electrically connecting a common electrode and a common voltage line is disposed in the display area, and is capable of implementing a narrow bezel by reducing a bezel width.

According to one or more embodiments of the present disclosure, a display device may be provided that includes a black bank and is capable of improving reflectivity and reflective visibility due to external light.

According to one or more embodiments of the present disclosure, a display device may be provided that includes a protection layer between a black bank and a light emitting element and is capable of preventing or at least reducing fume gas caused by the black bank from penetrating into the light emitting element.

According to one or more embodiments of the present disclosure, a display device may be provided that includes a structure capable of improving luminance unevenness and reflectivity and is capable of being driven with low power consumption.

Effects or advantages from aspects, examples, and embodiments described herein are not limited thereto, and additional effects or advantages will become apparent to those skilled in the art from the following description.

### BRIEF DESCRIPTION OF THE DRAWINGS

The accompanying drawings, which are included to provide a further understanding of the disclosure and are incorporated in and constitute a portion of the disclosure, illustrate embodiments of the disclosure and together with the description serve to explain principles of the disclosure. It should be therefore understood that aspects, examples, and embodiments described herein are not limited to the illustrations of the accompanying drawings. In the drawings:

FIG. 1 illustrates an example system configuration of a display device according to embodiments of the present disclosure;

FIG. 2 is an example plan view of the display panel according to embodiments of the present disclosure;

FIG. 3 is an enlarged view of example area A of FIG. 2 in the display panel according to embodiments of the present disclosure;

FIGS. 4 to 7 are example cross-sectional views taken along line I-I′ of FIG. 3 in the display panel according to embodiments of the present disclosure;

FIG. 8 is an example cross-sectional view taken along line II-II′ of FIG. 3 in the display panel according to embodiments of the present disclosure;

FIGS. 9 to 13 illustrate example processes of manufacturing the display panel according to embodiments of the present disclosure;

FIG. 14 is a plan view of an example display panel according to embodiments of the present disclosure;

FIGS. 15 and 16 are example cross-sectional views of the display panel according to embodiments of the present disclosure; and

FIG. 17 illustrates an example cross-sectional view of the display panel illustrated in FIG. 8 and an example cross-sectional view taken along line III-III′ in the display panel of FIG. 14 according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

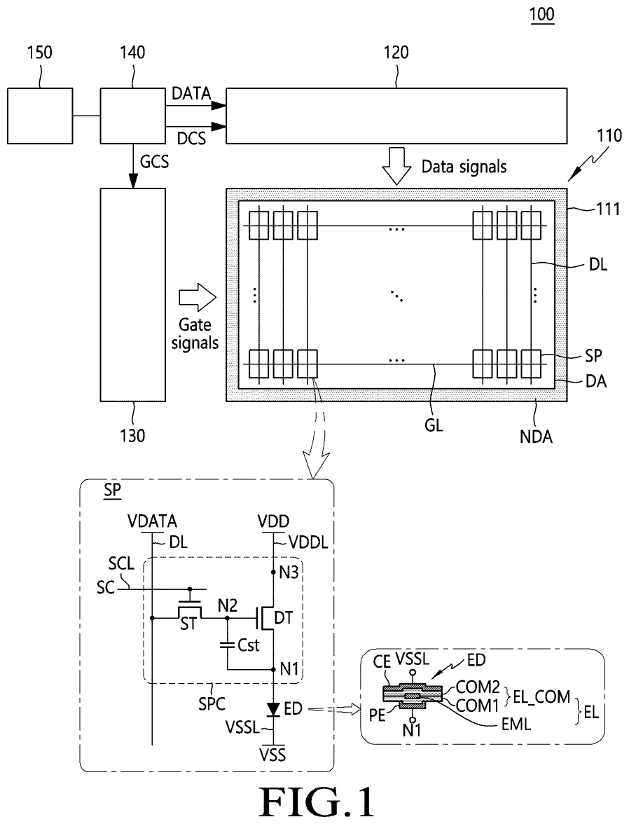

FIG. 1 illustrates an example system configuration of a display device 100 according to embodiments of the present disclosure.

Referring to FIG. 1, in one or more example embodiments, the display device 100 may include a display panel 110 and at least one display driving circuit, as elements for display images. The at least one display driving circuit may be a circuit for driving the display panel 110, and include a data driving circuit 120, a gate driving circuit 130, a controller 140, and other circuit components.

The display panel 110 may include a substrate 111 and a plurality of subpixels SP disposed on the substrate 111.

The substrate 111 may include a display area DA allowing an image to be displayed and a non-display area NDA located outside of the display area DA. The substrate 111 may include glass or be a flexible plastic substrate. In the example where a flexible plastic substrate is used as the substrate 111, the flexible plastic substrate may be polyimide or include polyamide.

The display area DA may also be referred to as an active area, and a plurality of subpixels SP for displaying images may be disposed in the display area DA. The non-display area NDA may also be referred to as a non-active area and include a pad area PA.

In one or more embodiments, the display panel 110 may be configured to have a very small non-display area NDA. The non-display area NDA may be also referred to as a “bezel” or an “bezel area.” For example, the non-display area NDA may include a first non-display area located outside of the display area DA in a first direction, a second non-display area located outside of the display area DA in a second direction, a third non-display area located outside of the display area DA in a direction opposite to the first direction, and a fourth non-display area located outside of the display area DA in a direction opposite to the second direction.

The first non-display area among the first to fourth non-display areas may include a pad area to which one or more driving circuits are connected or bonded. Among the first to fourth non-display areas, the second to fourth non-display areas may have a very small size compared to the first non-display area.

In another example, a boundary area may be defined between the display area DA and the non-display area NDA. In this example, the boundary area may be bent at a certain angle to the display area DA, and thereby, the non-display area NDA may be located under the display area DA. In this implementation, when a user views the display device 100 in front thereof, all or most of the non-display area NDA may be invisible to the user. For example, the first non-display area may include a bending area. As the bending area is bent, the first non-display area may be invisible in front of the display device 100.

Several types of signal lines for driving a plurality of subpixels SP may be disposed on the substrate 111 of the display panel 110.

In one or more embodiments, the display device 100 herein may be a liquid crystal display device, or the like, or a self-emission display device in which light is emitted from the display panel 110 itself. In an example where the display device 100 is the self-emission display device, each of the plurality of subpixels SP may include a light emitting element.

For example, the display device 100 according to embodiments of the present disclosure may be an organic light emitting display device in which light emitting elements are implemented using organic light emitting diodes (OLED). In another example, the display device 100 according to embodiments of the present disclosure may be an inorganic light emitting display device in which light emitting elements are implemented using inorganic material-based light emitting diodes. In further another example, the display device 100 according to embodiments of the present disclosure may be a quantum dot display device in which light emitting elements are implemented using quantum dots, which are self-emission semiconductor crystals.

The structure of each or at least one of a plurality of subpixels SP included in the display device 100 may depend on types of display device 100. For example, when the display device 100 is a self-emission display device including self-emission subpixels SP, each subpixel SP may include a self-emission light emitting element, one or more transistors, and one or more capacitors.

Referring to FIG. 1, each or at least one of the plurality of subpixels SP disposed in the display area DA may include a light emitting element ED and a subpixel circuit SPC configured to drive the light emitting element ED.

Referring to FIG. 1, the subpixel circuit SPC may include a plurality of transistors and at least one capacitor for driving the light emitting element ED. The subpixel circuit SPC can drive the light emitting element ED by supplying a driving current to the light emitting element ED at a predetermined timing. The light emitting element ED can emit light by being driven by the driving current.

The plurality of transistors may include a driving transistor DT for driving the light emitting element ED and a scan transistor ST configured to be turned on or off according to a scan signal SC.

The driving transistor DT can supply a driving current to the light emitting element ED.

The scan transistor ST may be configured to control an electrical state of a corresponding node in the subpixel circuit SPC or to control the state or operation of the driving transistor DT.

The at least one capacitor may include a storage capacitor Cst configured to maintain a voltage at a constant level during a display frame or a period of the display frame.

To drive one or more subpixels SP, at least one data signal VDATA, which is an image signal, and at least one scan signal SC, which is a gate signal, may be applied to the one or more subpixels SP. Further, to drive one or more subpixels SP, at least one common driving voltage including a first common driving voltage VDD and a second common driving voltage VSS may be applied to the one or more subpixels SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode disposed commonly in all or some of a plurality of subpixels SP. For example, the pixel electrode PE may be an anode electrode, and the common electrode CE may be a cathode electrode. In another example, the pixel electrode PE may be a cathode electrode, and the common electrode CE may be an anode electrode. Hereinafter, for convenience of explanation, discussions may be provided based on examples where the pixel electrode PE is an anode electrode, and the common electrode CE is a cathode electrode.

In an example where the light emitting element ED is an organic light emitting diode, the intermediate layer EL may include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 may be referred to as a common intermediate layer EL_COM.

In one or more embodiments, the emission layer EML may be disposed for each subpixel SP, and the common intermediate layer EL_COM may be commonly disposed across all or some of a plurality of subpixels SP.

For example, the emission layer EML may be disposed for each light emitting area, and the common intermediate layer EL_COM may be commonly disposed across a plurality of light emitting areas and a non-light emitting area.

In one or more embodiments, the emission layer EML and the common intermediate layer EL_COM may be commonly disposed across all or some of a plurality of subpixels SP.

For example, the emission layer EML and the common intermediate layer EL_COM may be commonly disposed across a plurality of light emitting areas and a non-light emitting area.

In one or more embodiments, the first common intermediate layer COM1 may include a hole injection layer (HIL), a hole transfer layer (HTL), and the like. The second common intermediate layer COM2 may include an electron transport layer (ETL), an electron injection layer (EIL), and the like.

The hole injection layer can inject holes from the pixel electrode PE to the hole transport layer, the hole transport layer can transport holes to the emission layer EML. The electron injection layer can inject electrons from the common electrode CE to the electron transport layer, and the electron transport layer can transport electrons to the emission layer EML.

In one or more embodiments, the common electrode CE may be electrically connected to a second common driving voltage line VSSL. A second common driving voltage VSS may be applied to the common electrode CE through the second common driving voltage line VSSL. The pixel electrode PE may be electrically connected directly or indirectly (via another transistor) to a first node N1 of the corresponding driving transistor DT of each subpixel SP. Herein, the second common driving voltage VSS may also be referred to as a “base voltage”, and the second common driving voltage line VSSL may also be referred to as a “low power supply voltage line”, a “low voltage line”, or a “base voltage line.

Each light emitting element ED may be configured by overlapping of a pixel electrode PE, an emission layer EML in an intermediate layer EL, and a common electrode CE. A corresponding light emitting area may be formed by each light emitting element ED. For example, a corresponding light emitting area of each light emitting element ED may include an area where a pixel electrode PE, an emission layer EML in an intermediate layer EL, and a common electrode CE overlap with each other.

In one or more embodiments, each or at least one of a plurality of light emitting elements ED included in the display panel 110 to the display device 100 may be an organic light emitting diode (OLED), an inorganic light emitting diode (LED), a quantum dot (QD) light emitting element, a micro light emitting diode, a mini light emitting diode, or the like, but embodiments of the present disclosure are not limited thereto. In the example where each or at least one of a plurality of light emitting elements ED included in the display panel 110 to the display device 100 is an organic light emitting diode (OLED), an intermediate layer EL included in the organic light emitting diode (OLED) may include an organic material.

Referring to FIG. 1, the driving transistor DT may be a transistor configured to supply a driving current to the light emitting element ED. The driving transistor DT may be connected between a first common driving voltage line VDDL and the light emitting element ED.

The driving transistor DT may include a first node N1, a second node N2, and a third node N3. The first node N1 may be electrically connected to the light emitting element ED. A data signal VDATA may be applied to the second node N2. A first common driving voltage VDD delivered through the first common driving voltage line VDDL may be applied to the third node N3.

In the driving transistor DT, the second node N2 may be a gate node, the first node N1 may be a source node or a drain node, and the third node N3 may be the drain node or the source node. Hereinafter, for merely convenience of explanation, discussions may be provided based on examples where the first, second, and third nodes (N1, N2, and N3) of the driving transistor DT are source, gate, and drain nodes, respectively. However, embodiments of the present disclosure are not limited thereto.

The scan transistor ST included in the subpixel circuit SPC illustrated in FIG. 1 may be a switching transistor for allowing a data signal VDATA, which is an image signal, to be supplied to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST may be electrically connected to the data line DL. The source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the second node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed to be located outside of the driving transistor DT, and therefore, be different from an internal capacitor such as a parasitic capacitor (e.g., a Cgs, a Cgd) that may be formed between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

In an example where the display panel 110 has the top emission structure, at least a portion of the subpixel circuit SPC may overlap with at least a portion of the light emitting element ED in the vertical direction. In this configuration, the area or size of a corresponding light emitting area can increase, and a corresponding aperture ratio can increase.

In an example where the display panel 110 has the bottom emission structure, the subpixel circuit SPC may not overlap with the light emitting element ED in the vertical direction.

As shown in FIG. 1, the subpixel circuit SPC may include two transistors (2T: DT and ST) and one capacitor (1C: Cst) (which may be referred to as a “2T1C structure”), and in some implementations, may further include one or more transistors, or further include one or more capacitors.

For example, the subpixel circuit SPC may have an 8T1C structure including 8 transistors and 1 capacitor. In further another example, the subpixel circuit SPC may have a 6T2C structure including 6 transistors and 2 capacitors. In further another example, the subpixel circuit SPC may have a 7T1C structure including 7 transistors and 1 capacitor. However, embodiments of the present disclosure are not limited to such specific structures.

The types and number of signals supplied to a subpixel SP, and/or the types and number of lines connected to the subpixel SP may vary depending on a structure of a corresponding subpixel circuit SPC. Further, the types and number of common driving voltages supplied to a subpixel SP may vary depending on a structure of a corresponding subpixel circuit SPC.

The several types of signal lines may include, for example, a plurality of data lines DL for carrying data signals (which may be referred to as data voltages or image signals), a plurality of gate lines GL for carrying gate signals (which may be referred to as scan signals), and the like.

In one or more embodiments, the plurality of data lines DL and the plurality of gate lines GL may intersect one another. Each of the plurality of data lines DL may be configured to extend in a first direction, and each of the plurality of gate lines GL may be configured to extend in a second direction. For example, the first direction may be the column direction, and the second direction may be the row direction. In another example, the first direction may be the row direction, and the second direction may be the column direction. Hereinafter, for merely convenience of explanation, discussions are provided based on examples where the first direction is the column direction and the second direction is the row direction. Hereinafter, for convenience of explanation, discussions may be provided based on examples where each of a plurality of data lines DL is disposed in the column direction, and each of a plurality of gate lines GL is disposed in the row direction, but embodiments of the present disclosure are limited thereto.

The data driving circuit 120 may be a circuit for driving a plurality of data lines DL and can output data signals to the plurality of data lines DL.

The data driving circuit 120 can receive image data DATA in digital form from the controller 140, convert the received image data DATA into data signals in analog form, and output the resulting data signals to the plurality of data lines DL.

In one or more embodiments, the data driving circuit 120 may be connected to the display panel 110 by a tape-automated-bonding (TAB) technology, or connected to a conductive pad such as a bonding pad of the display panel 110 by a chip-on-glass (COG) technology or a chip-on-panel (COP) technology, or connected to the display panel 110 by a chip-on-film (COF) technology. However, embodiments of the present disclosure are not limited thereto.

In one or more embodiments, the data driving circuit 120 may be disposed in, and/or electrically connected to, but not limited to, only one side or edge (e.g., an upper portion or a lower portion) of the display panel 110. In one or more embodiments, the data driving circuit 120 may be disposed in, and/or electrically connected to, but not limited to, two sides or portions (e.g., an upper edge and a lower edge) of the display panel 110 or at least two of four sides or portions (e.g., the upper edge, the lower edge, a left edge, and a right edge) of the display panel 110 according to driving schemes, panel design schemes, or the like.

The data driving circuit 120 may be connected to an area outward from the display area DA of the display panel 110 or be disposed in the display area DA of the display panel 110.

The gate driving circuit 130 may be a circuit for driving a plurality of gate lines GL and can output gate signals to the plurality of gate lines GL.

The gate driving circuit 130 can receive various types of gate driving control signals GCS, and further, receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

In one or more embodiments, the gate driving circuit 130 included in the display device 100 may be embedded into the display panel 110 by a gate-in-panel (GIP) technique. In an example where the gate driving circuit 130 is implemented by the gate-in-panel (GIP) technology, the gate driving circuit 130 may be disposed on the substrate 111 of the display panel 110 during the manufacturing process of the display panel 110 or display device 100.

In one or more embodiments, the gate driving circuit 130 may be disposed in the non-display area NDA of the display panel 110.

In one or more embodiments, the gate driving circuit 130 may be disposed in the display area DA of the display panel 110. In this implementation, for example, the gate driving circuit 130 may be disposed in, and/or electrically connected to, but not limited to, a first area (e.g., a left area or a right area) of the display area DA of the display panel 110. In another example, the gate driving circuit 130 may be disposed in, and/or electrically connected to, but not limited to, a first area (e.g., a left area or a right area) and a second area (e.g., the right area or the left area) of the display area DA of the display panel 110.

Herein, the gate driving circuit 130 embedded in the display panel 110 by the gate-in-panel (GIP) technique may also be referred to as a “gate-in-panel circuit.”

The controller 140 may be a device configured to control the data driving circuit 120 and the gate driving circuit 130, and can control driving timing for the plurality of data lines DL and driving timing for the plurality of gate lines GL.

The controller 140 can supply a data control signal DCS to the data driving circuit 120 to control the data driving circuit 120 and supply a gate control signal GCS to the gate driving circuit 130 to control the gate driving circuit 130.

The controller 140 can receive image data input from a host system 150 and supply image data DATA readable by the data driving circuit 120 based on the input image data to the data driving circuit 120.

The controller 140 may be implemented in a separate component from the data driving circuit 120, or integrated with the data driving circuit 120, so that the controller 140 and the data driving circuit 120 can be implemented in a single integrated circuit.

The controller 140 may be a timing controller used in the typical display technology or a control apparatus/device capable of additionally performing other control functionalities in addition to the typical function of the timing controller. In one or more embodiments, the controller 140 may be one or more other control circuits different from the timing controller, or a circuit or component in the control apparatus/device. The controller 140 may be implemented using various circuits or electronic components such as an integrated circuit (IC), a field programmable gate array (FPGA), an application specific integrated circuit (ASIC), a processor, and/or the like.

The controller 140 may be mounted on a printed circuit board, a flexible printed circuit, or the like, and may be electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces may include a low voltage differential signaling (LVDS) interface, an embedded clock point-point interface (EPI), a serial peripheral interface (SPI), and the like. However, embodiments of the present disclosure are not limited thereto.

In one or more embodiments, to provide a touch sensing function, as well as an image display function, the display device 100 may include a touch sensor, and a touch sensing circuit configured to sense the touch sensor and detect whether a touch is applied by an object such as a finger, a pen, or the like, or a location of the touch (or touch coordinates).

The touch sensing circuit may include a touch driving circuit configured to drive and sense the touch sensor and generate and output touch sensing data, and a touch controller configured to detect whether a touch is applied or a location of the touch (or touch coordinates) based on the touch sensing data.

The touch sensor may include a plurality of touch electrodes. The touch sensor may further include a plurality of touch lines for electrically connecting the plurality of touch electrodes to the touch driving circuit.

The touch sensor may be disposed outside of the display panel 110 in the form of a touch panel or may be disposed inside of the display panel 110. The touch sensor disposed outside of the display panel 110 may be referred to as an add-on type touch sensor. In the example where the add-on type of touch sensor is disposed in the display device 100, the touch panel and the display panel 110 may be separately manufactured and combined in an assembly process. The add-on type of touch panel may include a touch panel substrate and a plurality of touch electrodes disposed on the touch panel substrate.

In the example where the touch sensor is disposed inside of the display panel 110, the touch sensor may be formed on the substrate along with signal lines and electrodes related to display driving during the manufacturing process of the display panel 110.

The touch driving circuit can supply a touch driving signal to at least one of a plurality of touch electrodes and generate touch sensing data by sensing at least one of the plurality of touch electrodes.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on capacitance between each touch electrode and a touch object (e.g., a finger, a pen, and the like). According to the self-capacitance sensing technique, each of a plurality of touch electrodes can serve as both a driving touch electrode and a sensing touch electrode. The touch driving circuit may drive all, or one or more, of a plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes. According to the mutual-capacitance sensing technique, a plurality of touch electrodes may be divided into driving touch electrodes and sensing touch electrodes. The touch driving circuit can drive the driving touch electrodes and sense the sensing touch electrodes.

In one or more embodiments, the touch driving circuit and touch controller included in the touch sensing circuit may be implemented in separate devices or in a single device. In one or more embodiments, the touch driving circuit and the data driving circuit may be implemented in separate devices or in a single device.

The display device 100 may further include a power supply circuit for supplying several types of power to the display driving circuit and/or the touch sensing circuit.

In one or more embodiments, the display device 100 may be a mobile terminal such as a smart phone, a tablet, or the like, or a monitor, a television (TV), or the like. Such apparatuses may be configured in various types, sizes, and shapes. The display device 100 according to embodiments of the present disclosure are not limited thereto, and may include various types, sizes, and shapes configured to display information or images. The display device according to the embodiments of the present disclosure may be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display apparatuses, vehicle apparatuses, theater apparatuses, theater display apparatuses, televisions, wallpaper apparatuses, signage apparatuses, game apparatuses, notebook computers, monitors, cameras, camcorders, and home appliances, and the like.

In one or more embodiments, the display device 100 may further include an electronic device such as a camera (e.g., an image sensor), a sensor capable of detecting an object, ambient light, and the like. For example, the sensor may be a sensor capable of detecting an object or a human body by receiving light such as infrared light, ultrasonic light, ultraviolet light or the like.

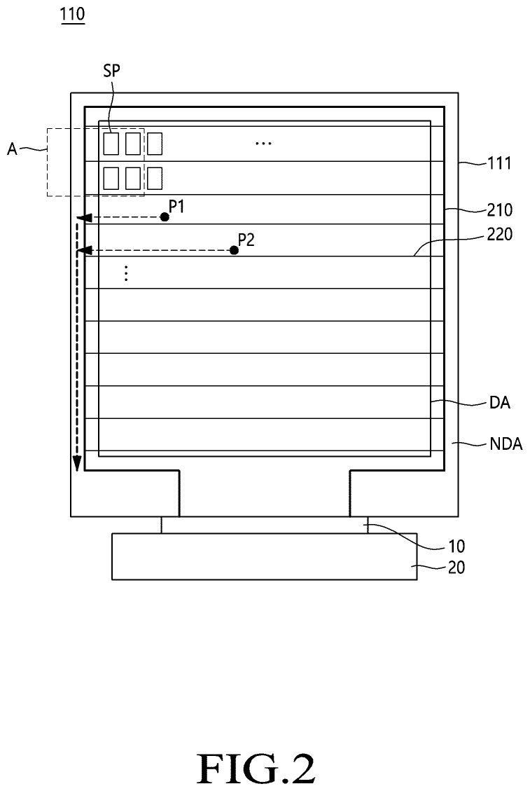

FIG. 2 is an example plan view of the display panel 110 according to embodiments of the present disclosure. In discussions that follow for the configuration of FIG. 2, discussions for features and configurations equal, substantially equal, or similar to the features and configurations described with reference to FIG. 1 are omitted or briefly described for simplicity.

Referring to FIG. 2, in one or more example embodiments, the display panel 110 may include a substrate 111, a printed circuit board 20 located outside of the substrate 111 and providing electrical signals, power supply voltages, and the like, and a flexible circuit board or connector 10 connecting the printed circuit board 20 to the substrate 111.

A common electrode CE may be disposed such that it extends from the display area DA to a portion of the non-display area NDA located outside of the display area DA and partially overlaps with a power supply voltage line. For example, the common electrode CE may be formed integrally in the display area DA and the portion of the non-display area NDA outside of the display area DA.

In one or more embodiments, the display panel 110 may include a structure in which the common electrode CE and one or more auxiliary lines 220 electrically contact each other in the display area DA, and through this structure, and thereby, can provide advantages of preventing a voltage drop of a common voltage VSS applied to the common electrode CE and improving luminance unevenness in each area of the display area DA. For example, a structure in which the common electrode CE and a power supply voltage line electrically contact each other through a connection electrode and the like may be formed in the non-display area NDA. However, this implementation may act as a hindrance in reducing a width of a bezel of the display panel 110 or the display device 100, which is the non-display area NDA, and therefore, it may be difficult to form the display panel 110 or the display device 100 with a narrow bezel.

The display area DA may include a plurality of light emitting areas, which are independently formed, spaced apart from each other, and respectively located in a plurality of subpixels SP disposed in the display area DA. In one or more embodiments, auxiliary lines 220 may be disposed to be spaced apart from each other in the display area DA. FIG. 2 shows an example in which auxiliary lines 220 are disposed to extend in a second direction (e.g., in the horizontal direction), but embodiments of the present disclosure are not limited thereto. For example, the auxiliary lines 220 may be disposed to extend in a first direction (e.g., in the column direction). In another example, the auxiliary lines 220 may be disposed to extend in both the first direction and the second direction. The auxiliary lines 220 may extend to a portion of the non-display area NDA outside of the display area DA and be electrically connected to a common voltage line 210. In this implementation, a common voltage VSS delivered through the common voltage line 210 may be applied to the auxiliary lines 220.

The display device 100 may include a structure where the auxiliary lines 220 is connected to the common electrode CE overlapping with the auxiliary lines 220. According to this structure, a common voltage supplied through the auxiliary lines 220 disposed in the display area DA can be supplied to the common electrode CE at multiple locations in the display area DA. Through this configuration, the common electrode CE can be supplied with a common voltage VSS by both the connection with the common voltage line 210 in the non-display area NDA and the connection with the auxiliary lines 220 in the display area DA. Thereby, the common electrode CE can supplied with a common voltage VSS with a uniform level at the whole area of the display area DA, and a voltage drop in the common electrode CE formed integrally can be prevented.

For example, referring to FIG. 2, a common voltage VSS with a substantially equal level can be applied to the common electrode CE in an area formed along an auxiliary line 220 connected to the common electrode CE from location P1 and an area formed along another auxiliary line 220 connected to the common electrode CE from location P2, in the display area DA. Accordingly, light emitting elements ED disposed in subpixels SP respectively located in the area formed along the auxiliary line 220 connected to the common electrode CE at location P1 and in the area formed along the auxiliary line 220 connected to the common electrode CE at location P2 can be provided with an equal (or substantially equal) amount of current without a change in an amount of current by the supply of the common voltage VSS with a substantially equal level without a voltage drop at the common electrode CE. This may mean that the corresponding light emitting elements ED may be provided with an substantially equal amount of current in any of the area formed along the auxiliary line 220 connected to the common electrode CE at location P1 and the area formed along the auxiliary line 220 connected to the common electrode CE at location P2, and thereby, may not represent different luminance caused by a difference in amounts of driving current when the light emitting elements ED are driven.

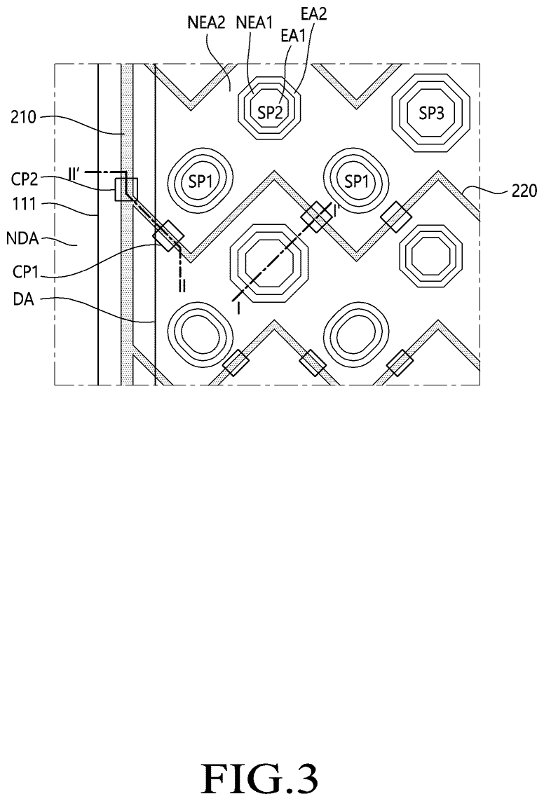

FIG. 3 is an enlarged view of example area A of FIG. 2 in the display panel 110 according to embodiments of the present disclosure. In discussions that follow for the configuration of FIG. 3, discussions for features and configurations equal, substantially equal, or similar to the features and configurations described with reference to FIGS. 1 and 2 are omitted or briefly described for simplicity.

Referring to FIG. 3, in one or more example embodiments, a plurality of subpixels SP may be disposed in the display area DA. An area of the display area DA where subpixels SP are disposed may be referred to as a subpixel area. An area of the display area DA where subpixels SP are not disposed may be referred to as a non-subpixel area. A subpixel may be a minimum unit for producing an image and mean a light emitting area.

A first subpixel SP1 may be a green subpixel emitting green light, a second subpixel SP2 may be a red subpixel emitting red light, and a third subpixel SP3 may be a blue subpixel emitting blue light. However, embodiments of the present disclosure are not limited thereto.

For example, each subpixel SP may include a first light emitting area EA1, a second light emitting area EA2, a first non-light emitting area NEA1, and a second non-light emitting area NEA2. The second light emitting area EA2 may be formed in a shape surrounding the first light emitting area EA1. The first non-light emitting area NEA1 may be located between the first light emitting area EA1 and the second light emitting area EA2 and be formed in a shape surrounding the first light emitting area EA1. The second non-light emitting area NEA2 may be formed in a shape surrounding the second light emitting area EA2.

Referring to FIG. 3, the first subpixel SP1, the second subpixel SP2, and the third subpixel SP3 may be disposed to be spaced apart from each other by a predetermined interval. For example, the second subpixel SP2 and the third subpixel SP3 may be disposed to be spaced apart from each other by a predetermined interval in the same row, and adjacent first subpixels SP1 may be disposed to be spaced apart from each other by a predetermined interval in an adjacent row. The arrangement of these subpixels SP may be repeated in adjacent rows. In this arrangement, at least one of the second subpixel SP2 and the third subpixel SP3 may have a size or area greater than the first subpixel SP1.

The first subpixel SP1, the second subpixel SP2, and the third subpixel SP3 may be disposed in a staggered pattern. For example, adjacent first subpixels SP1 may be disposed to be spaced apart from each other by a predetermined interval in the same column, and the second subpixel SP2 and the third subpixel SP3 may be disposed to be spaced apart from each other by a predetermined interval in an adjacent column. The arrangement of these subpixels SP may be repeated in adjacent columns.

Referring to FIG. 3, one or more auxiliary lines 220 may be disposed in the display area DA. The auxiliary lines 220 may be located in the non-subpixel area of the display area DA. The auxiliary lines 220 may be lines for applying a common voltage VSS, that is, lines for electrically connecting a common electrode CE and a common voltage line 210. The auxiliary lines 220 may be disposed in substantially the same layer as a pixel electrode PE and be a portion of a metal layer including the same material as the pixel electrode PE.

Each auxiliary line 220 may extend in a second direction between subpixels SP and be disposed to be spaced apart from each other in a first direction intersecting the second direction. The auxiliary lines 220 may be disposed to be spaced apart from each other, and subpixels SP may be disposed between two adjacent auxiliary lines 220. For example, the first subpixel SP1, the second subpixel SP2, and the third subpixel SP3 may be disposed between two adjacent auxiliary lines 220.

The auxiliary lines 220 may be disposed to extend in the second direction. For example, the auxiliary lines 220 may extend across a non-subpixel area between the first subpixel SP1 and the third subpixel SP3, a non-subpixel area between the third subpixel SP3 and the first subpixel SP2, and a non-subpixel area between the first subpixel SP1 and the second subpixel SP2. In this configuration, since the first subpixel SP1 is disposed in a staggered pattern in a different row from the second subpixel SP2 and the third subpixel SP3, each auxiliary line 220 may be disposed in a zigzag pattern on a plane between subpixels. The auxiliary lines 220 with the zigzag pattern may be disposed to be spaced apart from each other. The structure illustrated in FIG. 3 represents a portion of the display area DA, and the display area DA may have a structure where the configuration of FIG. 3 is repeated. Although FIG. 3 shows a structure in which the auxiliary lines 220 are disposed to extend in the second direction and have the zigzag pattern. However, embodiments of the present disclosure are not limited thereto. For example, the auxiliary lines 220 may have a structure in which the auxiliary lines 220 are disposed to extend in the first direction and have the zigzag pattern. In another example, among the auxiliary lines 220, one or more auxiliary lines 220 may have the zigzag pattern in the first direction, and one or more other auxiliary lines 220 may have the zigzag pattern in the second direction.

Each auxiliary line 220 may be electrically connected to the common electrode CE in a non-subpixel area between subpixels SP. In order for the auxiliary lines 220 to be electrically connected to the common electrode CE, respective upper surfaces or portions of the auxiliary lines 220 may include first contacts CP1 exposing respective portions of the auxiliary lines 220. For example, a first contact CP1 may expose a portion of an auxiliary line 220 and electrically connect the auxiliary line 220 to the common electrode CE. In this example, the first contact CP1 may overlap with a pattern on which the auxiliary line 220 is disposed. For example, at least one first contact CP1 for electrically connecting the auxiliary line 220 to the common electrode CE may be formed on the pattern on which the auxiliary line 220 is disposed.

In one or more embodiments, referring to FIG. 3, one or more first contacts CP1 may be disposed in one or more holes formed in one or more portions of among portions of the pattern on which each auxiliary line 220 is disposed. For example, a plurality of first contacts CP1 may be disposed on each auxiliary line 220 with a zigzag shape in a plan view. The holes formed by the first contacts CP1 may be circular, but embodiments of the present disclosure are not limited thereto. For example, the holes may have a polygonal shape such as a square. For example, at least one first contact CP1 may be disposed in a central portion in a non-subpixel area between at least one first subpixel SP1 and at least one third subpixel SP3, or in a central portion in a non-subpixel area between at least one first subpixel SP1 and at least one second subpixel SP2, as shown in FIG. 3. However, embodiments of the present disclosure are not limited thereto. For example, first contacts CP1 in the form of holes may be formed in any portions of an area overlapping each auxiliary line 220 with the zigzag pattern.

In one or more embodiments, one or more first contacts CP1 may be formed in a straight line shape on a plane along a pattern in which each auxiliary line 220 is disposed. For example, one or more first contacts CP1 may be formed in the same zigzag pattern as the auxiliary lines 220 along the pattern in which each auxiliary line 220 is disposed. In a configuration similar to the auxiliary lines 220, the first contacts CP1 may extend in the second direction along non-subpixel areas in which the first to third subpixels (SP1, SP2, and SP3) are not disposed in the display area DA.

Referring to FIG. 3, the auxiliary lines 220 may be electrically connected to the common voltage line 210 in the non-display area NDA. In order for the auxiliary lines 220 to be electrically connected to the common voltage line 210, second contacts CP2 may be disposed under the auxiliary lines 220.

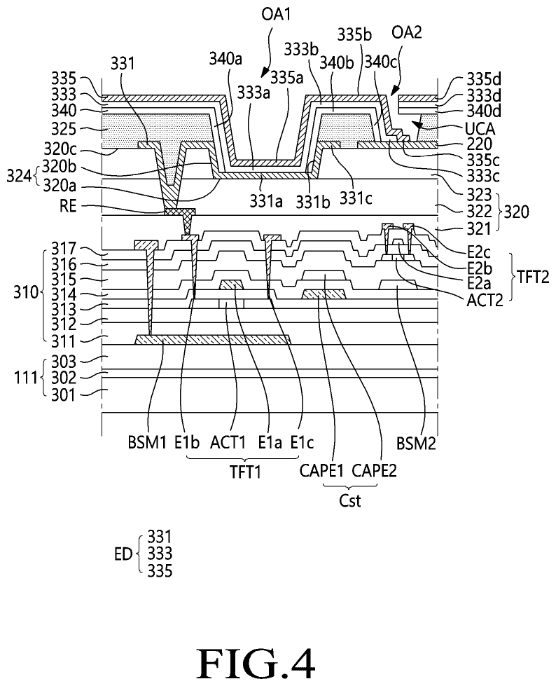

FIGS. 4 to 7 are example cross-sectional views taken along line I-I′ of FIG. 3 in the display panel 110 according to embodiments of the present disclosure. In discussions that follow for the configuration of FIGS. 4 to 7, discussions for features and configurations equal, substantially equal, or similar to the features and configurations described with reference to FIGS. 1 to 3 are omitted or briefly described for simplicity.

Referring to FIG. 4, in one or more example embodiments, in terms of stack-up configuration, the display panel 110 may include a transistor portion, a light emitting element portion, and an encapsulation portion.

A substrate 111 may be in the form of a single layer or multilayer. In an example where the substrate 111 is in the formed of a multilayer, the substrate 111 may include a first substrate 301, an intermediate substrate layer 302, and a second substrate 303. The intermediate substrate layer 302 may be located between the first substrate 301 and the second substrate 303. For example, each of the first substrate 301 and the second substrate 303 may be a polyimide (PI) layer. The intermediate substrate layer 302 may be an inorganic insulating layer. When charges are stored in the first substrate 301, which is the polyimide layer, the intermediate substrate layer 302 can block the charges from affecting one or more transistors disposed on the second substrate 303 through the second substrate 303, which is the polyimide layer.

In addition, the intermediate substrate layer 302 can block moisture from penetrating upwardly through the first substrate 301. For example, the intermediate substrate layer 302 may be in the form of a single layer of silicon nitride (SiNx) or silicon oxide (SiOx) or a multilayer thereof or may be in the form of a double layer of silicon dioxide (SiO2) and silicon nitride (SiNx). However, embodiments of the present disclosure are not limited thereto.

The transistor portion may include the substrate 111, several types of insulating layers (311, 312, 313, 314, 315, and 316) on the substrate 111, several types of transistors (TFT1 and TFT2), a storage capacitor Cst, and various electrodes or signal lines.

The transistors (TFT1 and TFT2) included in the transistor portion may include a first transistor TFT1 and a second transistor TFT2.

The first transistor TFT1 may include a first active layer ACT1, a first electrode E1a, a second electrode E1b, and a third electrode E1c. The first active layer ACT1 may be a first semiconductor layer, but embodiments of the present disclosure are not limited thereto. For example, the first active layer ACT1 may be configured with an oxide semiconductor, amorphous silicon, polysilicon, low-temperature polysilicon (LTPS), or the like, but embodiments of the present disclosure are not limited thereto. The first transistor TFT1 may be a p-channel transistor or an n-channel transistor, but embodiments of the present disclosure are not limited thereto.

The first electrode E1a may be a gate electrode, the second electrode E1b may be a source electrode or a drain electrode, and the third electrode E1c may be the drain electrode or the source electrode. Hereinafter, for convenience of explanation, discussions may be provided based on examples where the first, second, and third electrodes (E1a, E1b, and E1c) are a first gate electrode E1a, a first source electrode E1b, and a first drain electrode E1c, respectively. However, embodiments of the present disclosure are not limited thereto.

The second transistor TFT2 may include a second active layer ACT2, a fourth electrode E2a, a fifth electrode E2b, and a sixth electrode E2c. The second active layer ACT2 may be a second semiconductor layer, but embodiments of the present disclosure are not limited thereto. For example, the second active layer ACT2 may be configured with an oxide semiconductor, amorphous silicon, polysilicon, low-temperature polysilicon (LTPS), or the like, but embodiments of the present disclosure are not limited thereto. The second transistor TFT2 may be a p-channel transistor or an n-channel transistor, but embodiments of the present disclosure are not limited thereto.

For example, one of the first transistor TFT1 and the second transistor TFT2 may include an active layer formed from an oxide semiconductor. In another example, one of the first transistor TFT1 and the second transistor TFT2 may include an active layer formed from low-temperature polysilicon. In another example, the first transistor TFT1 and the second transistor TFT2 may include active layers formed from an oxide semiconductor. In another example, the first transistor TFT1 and the second transistor TFT2 may include active layers formed from low-temperature polysilicon. In another example, among the first transistor TFT1 and the second transistor TFT2, a driving transistor DT may include an active layer formed from an oxide semiconductor, and a scan transistor ST may include an active layer formed from low-temperature polysilicon. In another example, among the first transistor TFT1 and the second transistor TFT2, a driving transistor DT may include an active layer formed from low-temperature polysilicon, and a scan transistor ST may include an active layer formed from an oxide semiconductor. In another example, one or more transistors included in the gate driving circuit 130 configured in the gate-in-panel (GIP) type may include active layers including an oxide semiconductor or low temperature polysilicon. In another example, all of transistors disposed on the substrate 111 and transistors included in the gate driving circuit 130 configured in the gate-in-panel (GIP) type may include active layers including an oxide semiconductor.

The fourth electrode E2a may be a gate electrode, the fifth electrode E2b may be a source electrode or a drain electrode, and the sixth electrode E2c may be the drain electrode or the source electrode. Hereinafter, for convenience of explanation, discussions may be provided based on examples where the fourth, fifth, and sixth electrodes (E2a, E2b, and E2c) are a second gate electrode E2a, a second source electrode E2b, and a second drain electrode E2c, respectively. However, embodiments of the present disclosure are not limited thereto.

Although FIG. 4 illustrates that the second active layer ACT2 of the second transistor TFT2 is located higher from the substrate 111 than the first active layer ACT1 of the first transistor TFT1. However, embodiments of the present disclosure are not limited thereto. For example, the first active layer ACT1 of the first transistor TFT1 may be located higher from the substrate 111 than the second active layer ACT2 of the second transistor TFT2.

Further, although FIG. 4 illustrates that the second transistor TFT2 is located higher from the substrate 111 than the first transistor TFT1. However, embodiments of the present disclosure are not limited thereto. For example, the first transistor TFT1 may be located higher from the substrate 111 than the second transistor TFT2.

A first buffer layer (311 and/or 312) may be disposed under the first active layer ACT1 of the first transistor TFT1, and a second buffer layer 315 may be disposed under the second active layer ACT2 of the second transistor TFT2. For example, the first active layer ACT1 of the first transistor TFT1 may be located on the first buffer layer (311 and/or 312), and the second active layer ACT2 of the second transistor TFT2 may be located on the second buffer layer 315. The second buffer layer 315 may be located higher from the substrate 111 than the first buffer layer (311 and/or 312).

The storage capacitor Cst may be disposed in several metal layers in the display panel 110. For example, the storage capacitor Cst may include a first capacitor electrode CAPE1 and a second capacitor electrode CAPE2.

The light emitting element portion may include a plurality of light emitting elements ED disposed on an insulating layer 320. Each of the plurality of light emitting elements ED may include a first electrode 331, an intermediate layer 333, and a second electrode 335.

Hereinafter, the stack-up configuration of the display panel 110 is described in more detail with reference to FIG. 4.

Referring to FIG. 4, the first buffer layer (311 and/or 312) may be disposed on the substrate 111. The first buffer layer (311 and/or 312) may be in the form of a single layer or a multilayer. In an example where the first buffer layer (311 and/or 312) is in the form of a multilayer, the first buffer layer (311 and/or 312) may include a multi-buffer layer 311 and an active buffer layer 312.

Several types of transistors, at least one storage capacitor, and various electrodes or signal lines may be disposed on the first buffer layer (311 and/or 312). For example, the transistors disposed on the first buffer layer (311 and/or 312) may include a same material and be located in one or more same layers. For example, the transistors disposed on the first buffer layer (311 and/or 312) may include different materials and be located in one or more different layers.

The first active layer ACT1 of the first transistor TFT1 may be disposed on the first buffer layer (311 and/or 312). The first active layer ACT1 may include a channel region where a channel is formed, a source connection region on a first side of the channel region, and a drain connection region on a second opposing side of the channel region. The first active layer ACT1 may refer to an active layer of a transistor or may refer to a semiconductor layer including the same material as the active layer. Therefore, the first active layer ACT1 may be included in a transistor or be a circuit element and/or a signal line different from the transistor.

A first gate insulating layer 313 may be disposed on the first active layer ACT1 of the first transistor TFT1. The first gate insulating layer 313 may be in the formed of, for example, a single layer including silicon nitride (SiNx) or silicon oxide (SiOx) or a multilayer including silicon nitride (SiNx) and/or silicon oxide (SiOx). However, embodiments of the present disclosure are not limited thereto.

The first gate electrode E1a of the first transistor TFT1 may be disposed on the first gate insulating layer 313. The first gate electrode E1a may refer to a gate electrode of a transistor or may refer to a metal layer including the same material as the gate electrode. Therefore, the first gate electrode E1a may be included in a transistor or be a circuit element and/or a signal line different from the transistor. The first gate electrode E1a may include a conductive material. For example, the first gate electrode E1a may be in the form of a single layer or a multilayer including one or more, or one or more of alloys including two or more of molybdenum (Mo), aluminum (Al), chromium (Cr), gold (Au), titanium (Ti), nickel (Ni), neodymium (Nd), and copper (Cu). However, embodiments of the present disclosure are not limited thereto. For example, the first gate electrode E1a may include a stack of double layers of Mo and Ti.

A first interlayer insulating layer 314 may be disposed on the first gate electrode E1a of the first transistor TFT1. The first interlayer insulating layer 314 may be in the formed of, for example, a single layer including silicon nitride (SiNx) or silicon oxide (SiOx) or a multilayer including silicon nitride (SiNx) and/or silicon oxide (SiOx). However, embodiments of the present disclosure are not limited thereto.

The second buffer layer 315 may be disposed on the first interlayer insulating layer 314. The second buffer layer 315 may be in the formed of, for example, a single layer including silicon nitride (SiNx) or silicon oxide (SiOx) or a multilayer including silicon nitride (SiNx) and/or silicon oxide (SiOx). However, embodiments of the present disclosure are not limited thereto.

The second active layer ACT2 of the second transistor TFT2 may be disposed on the second buffer layer 315. The second active layer ACT2 may include a channel region where a channel is formed, a source connection region on a first side of the channel region, and a drain connection region on a second opposing side of the channel region. The second active layer ACT2 may refer to an active layer of a transistor or may refer to a semiconductor layer including the same material as the active layer. Therefore, the second active layer ACT2 may be included in a transistor or be a circuit element and/or a signal line different from the transistor.

A second gate insulating layer 316 may be disposed on the second active layer ACT2 of the second transistor TFT2. The second gate insulating layer 316 may be in the formed of, for example, a single layer including silicon nitride (SiNx) or silicon oxide (SiOx) or a multilayer including silicon nitride (SiNx) and/or silicon oxide (SiOx). However, embodiments of the present disclosure are not limited thereto.

The second gate electrode E2a of the second transistor TFT2 may be disposed on the second gate insulating layer 316. The second gate electrode E2a may refer to a gate electrode of a transistor or may refer to a metal layer including the same material as the gate electrode. Therefore, the second gate electrode E2a may be included in a transistor or be a circuit element and/or a signal line different from the transistor. The second gate electrode E2a may include a conductive material. For example, the second gate electrode E2a may be in the form of a single layer or a multilayer including one or more, or one or more of alloys including two or more of molybdenum (Mo), aluminum (Al), chromium (Cr), gold (Au), titanium (Ti), nickel (Ni), neodymium (Nd), and copper (Cu). However, embodiments of the present disclosure are not limited thereto. For example, the second gate electrode E2a may include a stack of double layers of Mo and Ti.

A second interlayer insulating layer 317 may be disposed on the second gate electrode E2a of the second transistor TFT2. The second interlayer insulating layer 317 may be in the formed of, for example, a single layer including silicon nitride (SiNx) or silicon oxide (SiOx) or a multilayer including silicon nitride (SiNx) and/or silicon oxide (SiOx). However, embodiments of the present disclosure are not limited thereto.

The first source electrode E1b and the first drain electrode E1c of the first transistor TFT1 and the second source electrode E2b and the second drain electrode E2c of the second transistor TFT2 may be disposed on the second interlayer insulating layer 317.

The first source electrode E1b and the first drain electrode E1c of the first transistor TFT1 may be electrically connected to the source connection region and the drain connection region of the first active layer ACT1 respectively through holes in the second interlayer insulating layer 317, the second gate insulating layer 316, the second buffer layer 315, the first interlayer insulating layer 314, and the first gate insulating layer 313.

The second source electrode E2b and the second drain electrode E2c of the second transistor TFT2 may be electrically connected to the source connection region and drain connection region of the second active layer ACT2 respectively through holes in the second interlayer insulating layer 317 and the second gate insulating layer 316.

The first source electrode E1b and the first drain electrode E1c of the first transistor TFT1 and the second source electrode E2b and the second drain electrode E2c of the second transistor TFT2 may include a first metal and may be disposed in a first metal layer. For example, the first metal and the first metal layer may be referred to as a first source-drain metal and a first source-drain metal layer, respectively, and the first metal layer may refer to a metal layer including the same material as the first source-drain metal. Therefore, the first source-drain electrode (E1b and E1c) may be included in a transistor or be a circuit element and/or a signal line different from the transistor. The first source-drain electrode (E1b and E1c) may include a conductive material. For example, the first source-drain electrode (E1b and E1c) may be in the form of a single layer or a multilayer including one or more, or one or more of alloys including two or more of molybdenum (Mo), aluminum (Al), chromium (Cr), gold (Au), titanium (Ti), nickel (Ni), neodymium (Nd), and copper (Cu). However, embodiments of the present disclosure are not limited thereto. For example, the first source-drain electrode (E1b and E1c) may include a stack of triple layers of Ti, Al, and Ti.

Referring to FIG. 4, in one or more embodiments, the storage capacitor Cst may be configured with the first capacitor electrode CAPE1 and the second capacitor electrode CAPE2. In one or more embodiments, the storage capacitor Cst may include three or more capacitor electrodes, or may include two or more capacitors connected in parallel.

Each of the first capacitor electrode CAPE1 and the second capacitor electrode CAPE2 may be disposed in several metal layers in the display panel 110.

In one or more embodiments, the first capacitor electrode CAPE1 may include the same first gate metal as the first gate electrode E1a of the first transistor TFT1 on the first gate insulating layer 313 and be disposed in a first gate metal layer.

In one or more embodiments, the second capacitor electrode CAPE2 may be disposed on the first interlayer insulating layer 314.

The second source electrode E2b of the second transistor TFT2 may be electrically connected to the second capacitor electrode CAPE2 through holes in the second interlayer insulating layer 317, the second gate insulating layer 316, and the second buffer layer 315.

For example, the first transistor TFT1 may be the scan transistor ST of FIG. 1, and the second transistor TFT2 may be the driving transistor DT of FIG. 1.

Referring to FIG. 4, the transistor portion may further include a first shield metal BSM1 disposed on the substrate 111, overlapping with the first active layer ACT1 of the first transistor TFT1, and disposed under the first active layer ACT1 of the first transistor TFT1. For example, the first shield metal BSM1 may be disposed between the substrate 111 and the first buffer layer (311 and/or 312) or may be disposed between the multi-buffer layer 311 and the active buffer layer 312.

The transistor portion may further include a second shield metal BSM2 disposed on the substrate 111, overlapping with the second active layer ACT2 of the second transistor TFT2, and disposed under the second active layer ACT2 of the second transistor TFT2.

For example, the second shield metal BSM2 may be disposed in a metal layer between the first interlayer insulating layer 314 and the second buffer layer 315. The second shield metal BSM2 may be disposed in the same metal layer as the second capacitor electrode CAPE2.

In another example, the second shield metal BSM2 may be disposed in the same first gate metal layer as the first gate electrode E1a of the first transistor TFT1.

An insulating layer 320 may be disposed on the first transistor TFT1 and the second transistor TFT2. The insulating layer 320 may be a planarization layer for flattening one or more functional layers in which the first transistor TFT1 and the second transistor TFT2 are disposed. The insulating layer 320 may include one or more materials among acrylic resin, epoxy resin, phenolic resin, polyamides resin, polyimides resin, unsaturated polyesters resin, polyphenylene resin, benzocyclobutene, and polyphenylene sulfides resin, but embodiments of the present disclosure are not limited thereto.

The insulating layer 320 may include at least one depression 324 in at least one subpixel. The insulating layer 320 may include at least one peripheral portion 320c surrounding the at least one depression 324 and located around the at least one depression 324.

The depression 324 may include a flat portion 320a and an inclined portion 320b surrounding the flat portion 320a. The surface of the flat portion 320a may be substantially parallel to a surface of the substrate 111. The inclined portion 320b may surround the flat portion 320a, and a surface of the inclined portion 320b may have a predefined angle with respect to the surface of the substrate 111. The surface of the inclined portion 320b may not be parallel to the surface of the substrate 111. For example, the surface of the inclined portion 320b may be an inclined surface having a predefined angle with respect to the surface of the substrate 111. The peripheral portion 320c may surround the inclined portion 320b and be located around the inclined portion 320b. The surface of the peripheral portion 320c may be substantially parallel to the surface of the substrate 111. To expose a relay electrode RE, a hole may be located in the peripheral portion 320c such that the hole is spaced apart from the inclined portion 320b.

The insulating layer 320 may be a single layer or a multilayer. For example, the insulating layer 320 illustrated in FIG. 4 may include a structure where three insulating layers (321, 322, and 323) are stacked on the first transistor TFT1 and the second transistor TFT2. For example, the insulating layer 320 may include a first insulating layer 321, a second insulating layer 322, and a third insulating layer 323, but embodiments of the present disclosure are not limited thereto. When the insulating layer 320 is a multilayer including the first insulating layer 321, the second insulating layer 322, and the third insulating layer 323, the first to third insulating layers (321, 322, and 323) may include the same insulating material as each other or include different insulating materials from each other.

For example, the first insulating layer 321 may be disposed on the first source electrode E1b and the first drain electrode E1c of the first transistor TFT1 and the second source electrode E2b and the second drain electrode E2c of the second transistor TFT2. For example, the first insulating layer 321 may be disposed to cover both the first transistor TFT1 and the second transistor TFT2. The first insulating layer 321 may include a hole for exposing the first source electrode E1b of the first transistor TFT1.

The relay electrode RE may be disposed on the first insulating layer 321. The relay electrode RE may be electrically connected to the first source electrode E1b of the first transistor TFT1 through a hole formed in the first insulating layer 321. In one or more embodiments, the first source electrode E1b of the first transistor TFT1 may be electrically connected to the first shield metal BSM1.

The relay electrode RE may be disposed in a second metal layer on the first insulating layer 321 and may include a second metal. The second metal and the second metal layer may be referred to as a second source-drain metal and a second source-drain metal layer, respectively. The second source-drain metal layer may refer to an electrode for electrically connecting the first source-drain electrode (E1b and E1c) and a light emitting element ED and may refer to a metal layer including the same material as this electrode. Therefore, the second source-drain metal layer may be included in an electrode for electrically connecting the first transistor TFT1 and the light emitting element ED or may be included in a circuit element and/or a signal line different from this electrode. The second source-drain metal layer may include a conductive material. For example, the second source-drain metal layer may be in the form of a single layer or a multilayer including one or more, or one or more of alloys including two or more of molybdenum (Mo), aluminum (Al), chromium (Cr), gold (Au), titanium (Ti), nickel (Ni), neodymium (Nd), and copper (Cu). However, embodiments of the present disclosure are not limited thereto. For example, the second source-drain metal layer may include a stack of triple layers of Ti, Al, and Ti.

The second insulating layer 322 may be disposed on the relay electrode RE. The second insulating layer 322 may include a hole for exposing the relay electrode RE. The second insulating layer 322 may include a flat portion 320a.

The third insulating layer 323 may be disposed on the second insulating layer 322. The third insulating layer 323 may include a hole for exposing the relay electrode RE. The third insulating layer 323 may include the inclined portion 320b and the peripheral portion 320c.

Referring to FIG. 4, the second insulating layer 322 may include the flat portion 320a, and the third insulating layer 323 may include the inclined portion 320b and the peripheral portion 320c. For example, the flat portion 320a may represent a portion of an upper surface of the second insulating layer 322. The inclined portion 320b may extend from a portion of the upper surface of the second insulating layer 322 to an upper surface of the third insulating layer 323 and may represent a surface having a predefined angle with respect to the surface of the substrate 111. The peripheral portion 320c may represent an upper surface of the third insulating layer 323. However, embodiments of the present disclosure are not limited thereto. For example, the third insulating layer 323 may include all of the flat portion 320a, the inclined portion 320b, and the peripheral portion 320c.

Referring to FIG. 4, the light emitting element portion may be disposed on the insulating layer 320. A light emitting element ED electrically connected to the relay electrode RE through a hole may be disposed on the insulating layer 320. For example, the light emitting element ED may be disposed on the second insulating layer 322 and the third insulating layer 323.

The light emitting element ED may include a first electrode 331 electrically connected to the first source electrode E1b of the first transistor TFT1, an intermediate layer 333 disposed on the first electrode 331, and a second electrode 335 disposed on the intermediate layer 333. The first electrode 331, the intermediate layer 333, and the second electrode 335 may correspond to the pixel electrode PE, the intermediate layer EL, and the common electrode CE of FIG. 1, respectively. FIG. 4 illustrates that the first electrode 331 is electrically connected to the first source electrode E1b of the first transistor TFT1, but embodiments of the present disclosure are not limited thereto. For example, the first electrode 331 may be electrically connected to the first drain electrode E1c of the first transistor TFT1.

The first electrode 331 may include a first portion 331a having a surface substantially parallel to the surface of the substrate 111 in an area overlapping with the depression 324, and a second portion 331b extending from the first portion 331a and having a surface inclined at a predefined angle with respect to the substrate 111. The surface of the second portion 331b may not be parallel to the surface of the substrate 111. The first portion 331a may be an area overlapping with the flat portion 320a. The second portion 331b may be an area overlapping with the inclined portion 320b. The first electrode 331 may include a third portion 331c extending from the second portion 331b and having a surface substantially parallel to the surface of the substrate 111. The third portion 331c may be an area overlapping with the peripheral portion 320c. For example, the first portion 331a may correspond to the flat portion 320a included in the second insulating layer 322. The second portion 331b may correspond to the inclined portion 320b of the third insulating layer 323. The third portion 331c may correspond to the peripheral portion 320c of the third insulating layer 323.

An auxiliary line 220 may be disposed on the insulating layer 320. The auxiliary line 220 may be disposed on the peripheral portion 320c of the insulating layer 320 and be spaced apart from the first electrode 331. The auxiliary line 220 may include a material included in the first electrode 331. The auxiliary line 220 may be disposed in substantially the same layer as the first electrode 331. For example, the auxiliary line 220 may be disposed on the peripheral portion 320c of the third insulating layer 323 and be spaced apart from the first electrode 331.

A bank 325 may be disposed on the insulating layer 320, a portion of the first electrode 331, and a portion of the auxiliary line 220. The bank 325 may be disposed on respective portions of the first electrode 331, the insulating layer 320, and the auxiliary line 220 in an area corresponding to the peripheral portion 320c of the insulating layer 320. The bank 325 may be disposed on respective portions of the first electrode 331, the insulating layer 320, and the auxiliary line 220 in an area corresponding to the peripheral portion 320c of the third insulating layer 323. The bank 325 may expose the first portion 331a and the second portion 331b of the first electrode 331 in an area overlapping with the depression 324. The bank 325 may be disposed to cover the third portion 331c of the first electrode 331 in an area overlapping the peripheral portion 320c of the insulating layer 320 and be disposed to expose a portion of the third portion 331c of the first electrode 331. For example, the bank 325 may be disposed to expose a portion of the third portion 331c of the first electrode 331 adjacent to the second portion 331b of the first electrode 331. The bank 325 may be disposed to expose a portion of the upper surface of the auxiliary line 220 in an area overlapping with the peripheral portion 320c of the insulating layer 320.

The bank 325 may include a first open area OA1 overlapping with the depression 324 and a second open area OA2 exposing at least a portion of the auxiliary line 220. In the first open area OA1, the bank 325 may be disposed to not overlap (e.g., non-overlapping) with the first portion 331a and the second portion 331b of the first electrode 331. For example, in the first open area OA1, the second portion 331b of the first electrode 331 and at least one first side surface of the bank 325 may include an inclined surface on the same plane. In a plan view, the first open area OA1 may overlap with the first portion 331a of the first electrode 331, and the second open area OA2 may overlap with a portion of the auxiliary line 220.

The bank 325 may include a transparent insulating resin such as a polyimide resin, an acrylic resin, a benzocyclobutene resin, or the like, but embodiments of the present disclosure are not limited thereto.

For example, the bank 325 may be a black bank having a high light absorption rate. In this example, the black bank can absorb light traveling toward adjacent subpixels and prevent color mixing between subpixels SP. Further, the black bank can absorb light incident on the display panel 110 from the outside, reduce reflectivity, and improve reflective visibility.

For example, the black bank may be formed by dispersing a colorant in a transparent insulating resin. For example, the colorant may be selected from a carbon-based pigment, a metal oxide-based pigment, or an organic pigment. For example, the carbon pigment may be selected from carbon black, carbon nanotubes, vanta black, or the like, but embodiments of the present disclosure are not limited thereto. For example, the metal oxide pigment may be titanium black (TiNxOy), or Cu—Mn—Fe-based black pigment, but embodiments of the present disclosure are not limited thereto. For example, the organic pigment may be selected from lactam black, perylene black, or aniline black, but embodiments of the present disclosure are not limited thereto. In another example, the colorant may be a mixture of two or more pigments or dyes having different colors.

A protection layer 340 may be disposed on the bank 325 and the first electrode 331. The protection layer 340 may include a first portion 340a, a second portion 340b, and a third portion 340c.

The first portion 340a of the protection layer 340 may be disposed to correspond to the inclined portion 320b of the depression 324. For example, in the first open area OA1, the first portion 340a of the protection layer 340 may be disposed on the whole second portion 331b of the first electrode 331 and the whole at least one first side surface of the bank 325.

The second portion 340b of the protection layer 340 may be disposed on an upper surface of the bank 325 disposed in the peripheral portion 320c. For example, the second portion 340b of the protection layer 340 may extend from the first portion 340a of the protection layer 340 and be disposed on the whole upper surface of the bank 325 between the first open area OA1 and the second open area OA2.

The third portion 340c of the protection layer 340 may be disposed on the whole second side surface of the bank 325 disposed in the peripheral portion 320c. For example, the third portion 340c of the protection layer 340 may extend from the second portion 340b of the protection layer 340 and be disposed on the whole second side surface of the bank 325 in the second open area OA2. In this example, the third portion 340c of the protection layer 340 may contact an upper surface of the auxiliary line 220 disposed in the second open area OA2, but embodiments of the present disclosure are not limited thereto.

The protection layer 340 may further include a fourth portion 340d disposed on a second side bank 325 spaced apart from a first side bank 325 where the third portion 340c of the protection layer 340 is disposed in the second open area OA2. Herein, the first side bank 325 and the second side bank 325 may be referred to as adjacent portions of the bank 325 located on a side of the bank 325 in the cross-sectional view. For example, the fourth portion 340d of the protection layer 340 may be disposed such that the fourth portion 340d extends from an upper surface of the second side bank 325 and protrudes toward the second open area OA2.

Referring to FIG. 4, an undercut area UCA may be formed under the protection layer 340. The undercut area UC may be an area where the bank 325 is not disposed under the protection layer 340. In the undercut area UCA, the protection layer 340 may protrude beyond the bank 325. For example, in the undercut area UCA, the fourth portion 340d of the protection layer 340 may protrude beyond the second side bank 325. In the second open area OA2, the fourth portion 340d of the protection layer 340 and the auxiliary line 220 may be spaced apart from each other, but the fourth portion 340d of the protection layer 340 and the auxiliary line 220 may overlap with each other in a plan view.

The protection layer 340 may include a transparent inorganic insulating material. The protection layer 340 may be in the form of a single layer of silicon nitride (SiNx), silicon oxide (SiOx), or silicon oxynitride (SiOxNy), or a multilayer thereof, but embodiments of the present disclosure are not limited thereto.

The intermediate layer 333 including at least one emission layer may be disposed on the protection layer 340 and the first electrode 331. The intermediate layer 333 may be formed by a deposition or coating method having straightness. For example, the intermediate layer 333 may be formed by a physical vapor deposition (PVD) method such as an evaporation process. The intermediate layer 333 may include a first portion 333a, a second portion 333b, and a third portion 333c.

The first portion 333a of the intermediate layer 333 may be disposed to correspond to the flat portion 320a and the inclined portion 320b of the depression 333. For example, in the first open area OA1, the first portion 333a of the intermediate layer 333 may be disposed on the first portion 331a of the first electrode 331 and the first portion 340a of the protection layer 340.

The second portion 333b of the intermediate layer 333 may be disposed on the upper surface of the bank 325 disposed in the peripheral portion 320c. For example, the second portion 333b of the intermediate layer 333 may extend from the first portion 333a of the intermediate layer 333 and be disposed on the second portion 340b of the protection layer 340 between the first open area OA1 and the second open area OA2.

The third portion 333c of the intermediate layer 333 may be disposed on the whole second side surface of the bank 325 disposed in the peripheral portion 320c. For example, the third portion 333c of the intermediate layer 333 may extend from the second portion 333b of the intermediate layer 333 and be disposed on the third portion 340c of the protection layer 340 in the second open area OA2. In this example, the third portion 333c of the intermediate layer 333 may extend to a portion of the upper surface of the auxiliary line 220 disposed in the second open area OA2, and not overlap with the fourth portion 340d of the protection layer 340. However, embodiments of the present disclosure are not limited thereto. For example, the intermediate layer 333 may not be disposed in the undercut area UCA, but embodiments of the present disclosure are not limited thereto.

The intermediate layer 333 may further include a fourth portion 333d spaced apart from the third portion 333c of the intermediate layer 333. For example, the fourth portion 333d of the intermediate layer 333 may be disposed on the fourth portion 340d of the protection layer 340. In the undercut area UCA, the intermediate layer 333 may protrude beyond the bank 325. For example, in the undercut area UCA, the fourth portion 333d of the protection layer 333 may protrude beyond the second side bank 325. In the second open area OA2, the fourth portion 333d of the intermediate layer 333 and the auxiliary line 220 may be spaced apart from each other, but the fourth portion 333d of the intermediate layer 333 and the auxiliary line 220 may overlap with each other in a plan view. In the second open area OA2, the third portion 333c and the fourth portion 333d of the intermediate layer 333 may be disposed not to overlap with each other in the plan view.

The second electrode 335 may be disposed on the intermediate layer 333. The second electrode 335 may be disposed along the shape of the intermediate layer 333. The second electrode 335 may be formed by a deposition method with an irregular direction. For example, the second electrode 335 may be formed by a deposition process with an irregular direction such as sputtering. The second electrode 335 may include a first portion 335a, a second portion 335b, and a third portion 335c.

The first portion 335a of the second electrode 335 may be disposed such that the first portion 335a corresponds to the first portion 333a of the intermediate layer 333 and the flat portion 320a and the inclined portion 320b of the depression 324. For example, in the first open area OA1, the first portion 335a of the second electrode 335 may be disposed on the first portion 333a of the intermediate layer 333.

The second portion 335b of the second electrode 335 may be disposed on the upper surface of the bank 325 disposed in the peripheral portion 320c. For example, the second portion 335b of the second electrode 335 may extend from the first portion 335a of the second electrode 335 and be disposed on the second portion 333b of the intermediate layer 333 between the first open area OA1 and the second open area OA2.

The third portion 335c of the second electrode 335 may be disposed on the whole second side surface of the bank 325 disposed in the peripheral portion 320c. For example, the third portion 335c of the second electrode 335 may extend from the second portion 335b of the second electrode 335 and be disposed to cover the third portion 333c of the intermediate layer 333 in the second open area OA2. In this example, the third portion 335c of the second electrode 335 may cover a portion of the third portion 333c of the intermediate layer 333, which is formed by extending to a portion of the upper surface of the auxiliary line 220 in the second open area OA2 and be disposed on a portion of the upper surface of the auxiliary line 220. For example, the third portion 335c of the second electrode 335 may be disposed such that the third portion 335c extends to the undercut area UCA.

The second electrode 335 may further include a fourth portion 335d spaced apart from the third portion 335c of the second electrode 335. For example, the fourth portion 335d of the second electrode 335 may be disposed on the fourth portion 333d of the intermediate layer 333. The second electrode 335 may protrude beyond the bank 325 in the undercut area UCA. For example, the fourth portion 335d of the second electrode 335 may protrude beyond the second side bank 325 in the undercut area UCA. In the second open area OA2, the fourth portion 335d of the second electrode 335 and the auxiliary line 220 may be spaced apart from each other, but the fourth portion 340d of the second electrode 335 and the auxiliary line 220 may overlap with each other in a plan view. The third portion 335c and the fourth portion 335d of the second electrode 335 may be spaced apart from each other in the second open area OA2, but the third portion 335c and the fourth portion 335d of the second electrode 335 may overlap with each other in the plan view.

Referring to FIG. 4, as the fourth portion 340d of the protection layer 340 is located to protrude beyond the bank 325, each of the intermediate layer 333 and the second electrode 335 located on the protection layer 340 may have a disconnected structure. For example, the intermediate layer 333 and the second electrode 335 may be difficult to be deposited in the undercut area UCA under the protection layer 340 due to the shadow effect. Therefore, the intermediate layer 333 may be formed discontinuously, and for example, be divided into a first part located on a first side and a second part located on a second opposing side in an area corresponding to the second open area OA2 in the cross-sectional view. Further, the second electrode 335 may be formed discontinuously, and for example, be divided into a first part located on the first side and a second part located on the second opposing side in the area corresponding to the second open area OA2 in the cross-sectional view.

The intermediate layer 333 may be formed by a deposition process having straightness such as evaporation, and the second electrode 335 may be formed by a deposition process having an irregular direction such as sputtering. According to these implementations, the intermediate layer 333 may not be formed under the fourth portion 340d of the protection layer 340, while the second electrode 335 may be formed by extending to a portion under the fourth portion 340d of the protection layer 340. Therefore, the second electrode 335 may be easily electrically connected to the auxiliary line 220 in the second open area OA2. Thereby, the display panel 110 can provide advantages of reducing the resistance of the second electrode 335 and improving the luminance uniformity.

In discussions that follow for configurations illustrated in figures below, for convenience of description, the expression of transistors (TFT1 and TFT2) and a storage capacitor Cst are omitted, and the first buffer layer (311, 312), the first gate insulating layer 313, the first interlayer insulating layer 314, the second buffer layer 315, the second gate insulating layer 316, and the second interlayer insulating layer 317, which have been discussed above with reference to previous figures, are collectively referred to as a TFT array substrate 310. However, it should be noted that although the omitted configurations may be applied equally or similarly, a structure where the omitted configurations are disposed may not be limited to the configurations illustrated in FIG. 4.

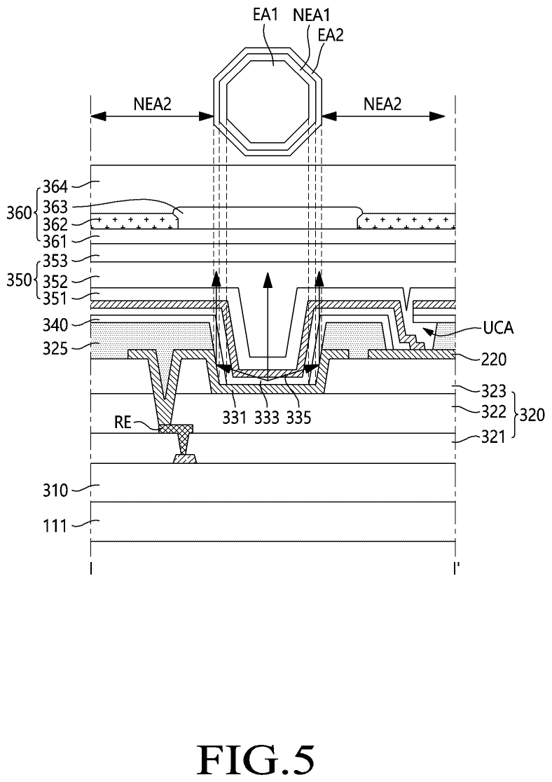

FIG. 5 is another example cross-sectional view taken along line I-I′ of FIG. 3 in the display panel 110 according to embodiments of the present disclosure. In discussions that follow for the configuration of FIG. 5, discussions for features and configurations equal, substantially equal, or similar to the features and configurations described with reference to FIGS. 1 to 4 are omitted or briefly described for simplicity.

Referring to FIG. 5, in one or more example embodiments, the display panel 110 may include a substrate 111, and a TFT array substrate 310, an insulating layer 320, a bank 325, a first electrode 331, an intermediate layer 333, a second electrode 335, and a protection layer 340, which are disposed on the substrate 111.

Referring to FIG. 5, an encapsulation portion may be disposed on a light emitting element portion and be located on the second electrode 335. The encapsulation portion may include an encapsulation layer 350 disposed on the second electrode 335.

The encapsulation layer 350 may prevent or at least reduce moisture or oxygen from penetrating into a light emitting element ED. For example, the encapsulation layer 350 may prevent moisture or oxygen from penetrating into an organic material included in the intermediate layer 333 of the light emitting element ED. For example, the encapsulation layer 350 may be in the form of a single layer or multilayer, but embodiments of the present disclosure are not limited thereto.

Referring to FIG. 5, for example, the encapsulation layer 350 may include a first encapsulation layer 351, a second encapsulation layer 352, and a third encapsulation layer 353. The first encapsulation layer 351 and the third encapsulation layer 353 may include, for example, inorganic layers, and the second encapsulation layer 352 may include, for example, an organic layer.

A color filter layer 360 may be disposed on the encapsulation layer 350.

A third buffer layer 361 may be disposed on the third encapsulation layer 353.

A black matrix 362 and at least one color filter 363 may be disposed on the third buffer layer 361. The black matrix 362 and the color filter 363 may have an anti-reflection function for minimizing the degradation of the visibility and contrast ratio of the display device 100 due to external light by absorbing external light while maintaining the luminescence of light emitted from the light emitting element ED at a high level.

The black matrix 362 may be disposed on the third buffer layer 361 such that the black matrix 362 overlaps with at least a portion of the bank 325. The black matrix 362 may define the at least one color filter 363. Accordingly, the black matrix 362 can minimize color mixing between adjacent subpixels SP. The black matrix 362 can absorb external light. Accordingly, the deterioration of the visibility and contrast ratio of the display device 100 due to external light can be minimized.

A width of the black matrix 362 may be less than a width of the bank 325 corresponding thereto. For example, at least one side of the bank 325 may protrude toward a light emitting area of the light emitting element ED more than at least one corresponding side of the black matrix 362. According to this example, viewing angle luminance and color viewing angle can become excellent.

The black matrix 362 may include an organic material. The black matrix 362 may include a base resin and a colorant. The base resin may be at least one selected from a cardo-based resin, an epoxy-based resin, an acrylate-based resin, a siloxane-based resin, or a polyimide, but embodiments of the present disclosure are not limited thereto. For example, the colorant may be selected from a carbon-based pigment, a metal oxide-based pigment, or an organic pigment. For example, the carbon pigment may be selected from carbon black, carbon nanotubes, vanta black, or the like, but embodiments of the present disclosure are not limited thereto. For example, the metal oxide pigment may be titanium black (TiNxOy), or Cu—Mn—Fe-based black pigment, but embodiments of the present disclosure are not limited thereto. For example, the organic pigment may be selected from lactam black, perylene black, or aniline black, but embodiments of the present disclosure are not limited thereto. In another example, the colorant may be a mixture of two or more pigments or dyes having different colors.

The color filter 363 may be disposed on the third buffer layer 361 to overlap with the light emitting element ED on the insulating layer 320. The color filter 363 may be disposed to cover a portion of the black matrix 362.

Although FIG. 5 illustrates a structure in which the black matrix 362 and the color filter 363 are disposed on the third buffer layer 361. However, embodiments of the present disclosure are not limited thereto. For example, the third buffer layer 361 may not be disposed, and the black matrix 362 and the color filter 363 may be disposed on the third encapsulation layer 353.

A color filter protection layer 364 may be disposed to cover the black matrix 362 and the color filter 363.

Referring to FIG. 5, a subpixel SP may include a first light emitting area EA1, a second light emitting area EA2, a first non-light emitting area NEA1, and a second non-light emitting area NEA2. The second light emitting area EA2 may be disposed in a shape surrounding the first light emitting area EA1. The first non-light emitting area NEA1 may be located between the first light emitting area EA1 and the second light emitting area EA2 and be disposed in a shape surrounding the first light emitting area EA1. The second non-light emitting area NEA2 may be disposed in a shape surrounding the second light emitting area EA2.

The first light emitting area EA1 may corresponding to an area where the first electrode 331, the intermediate layer 333, and the second electrode 335 overlap with each other. For example, the first light emitting area EA1 may correspond to an area where light emitted from the light emitting element ED is emitted. The second light emitting area EA2 may correspond to an area where light emitted from the light emitting element ED is reflected from a second portion 331b of the first electrode 331 and directed.

The first non-light emitting area NEA1 may correspond to an area where a portion of a first portion 331a of the first electrode 331 disposed on a flat portion 320a of a depression 324 of the insulating layer 320 overlaps with the protection layer 340. The second non-light emitting area NEA2 may correspond to an area between adjacent subpixels SP, for example, an area between respective second light emitting area EA2 of adjacent subpixels SP.

Discussions for the light emitting areas and the non-light emitting areas of subpixels SP are provided in more detail below.

The first electrode 331 may include a reflective metal.

FIG. 5 illustrates that the first electrode 331 is in the form of a single layer for convenience of explanation, but embodiments of the present disclosure are not limited thereto. For example, the first electrode 331 may have a multilayer structure. In the example in which the first electrode 331 has a multilayer structure, at least one layer may include a reflective metal.

For example, the first electrode 331 may have multilayer structure including a transparent layer including a transparent conductive film, and a reflective layer including an opaque conductive film with high reflection efficiency. For example, the transparent conductive film may include a material having a relatively large work function value, such as indium tin oxide (ITO) or indium zinc oxide (IZO), and the opaque conductive film may have a single layer or multilayer structure including aluminum (Al), silver (Ag), copper (Cu), lead (Pb), molybdenum (Mo), or titanium (Ti), or an alloy thereof. For example, the first electrode 331 may have a structure in which a transparent conductive film, an opaque conductive film, and a transparent conductive film are sequentially stacked, or a structure in which a transparent conductive film and an opaque conductive film are sequentially stacked.

In one or more embodiments, a second portion 331b of the first electrode 331 may be disposed on a corresponding side surface of at least one inclined portion 320b of the insulating layer 320 along a shape of the inclined portion 320b. The second portion 331b of the first electrode 331 disposed on the side surface of the at least one inclined portion 320b of the insulating layer 320 may have an inverse taper shape that is inclined from the first portion 331a of the first electrode 331 toward a third portion 331c. However, embodiments of the present disclosure are not limited thereto. The second portion 331b of the first electrode 331 including the reflective layer may serve as a side reflective layer.

In this structure, the second portion 331b of the first electrode 331 may serve as a reflective layer to reflect light emitted from the light emitting element ED upward. Light emitted from the intermediate layer 333 of the light emitting element ED may not only travel upward, but also travel sideward. For example, the second portion 331b of the first electrode 331 including the reflective layer may be disposed to cover the side surface of the at least one inclined portion 320b of the insulating layer 320, and thereby, light traveling sideward may be directed to move upward. That is, the second light emitting area EA2 may be formed. According to this configuration, the light extraction efficiency of the display device 100 can be improved.

The second electrode 335 may be disposed to face the first electrode 331 with the intermediate layer 333 interposed therebetween. Thus, the second electrode 335 may be disposed on the intermediate layer 333.

The second electrode 335 may include a conductive material capable of transmitting or semi-transmitting light. For example, the second electrode 335 may include at least one transparent conductive oxide, such as ITO, IZO, indium tin zinc oxide (ITZO), zinc oxide, tin oxide, or the like, or include a semi-transparent metal, such as magnesium (Mg), silver (Ag), or an alloy of magnesium and silver.

For example, when the second electrode 335 includes a semi-transparent metal, a thickness of the second electrode 335 may be less than a thickness of the first electrode 331.

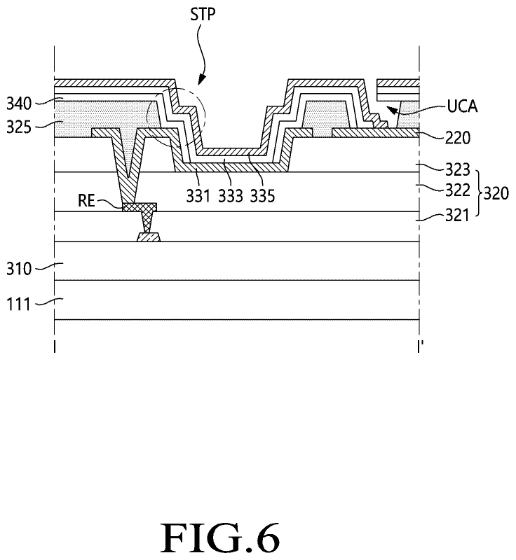

FIG. 6 is another example cross-sectional view taken along line I-I′ of FIG. 3 in the display panel 110 according to embodiments of the present disclosure. In discussions that follow for the configuration of FIG. 6, discussions for features and configurations equal, substantially equal, or similar to the features and configurations described with reference to FIGS. 1 to 5 are omitted or briefly described for simplicity.

Referring to FIG. 6, in one or more example embodiments, the display panel 110 may include a substrate 111, and a TFT array substrate 310, an insulating layer 320, a bank 325, a first electrode 331, an intermediate layer 333, a second electrode 335, and a protection layer 340, which are disposed on the substrate 111.

Referring to FIG. 6, the display panel 110 may include a step portion STP located at a peripheral portion 320c of the insulating layer 320.

The step portion STP may be formed such that the bank 325 exposes a portion of a third portion 331c of the first electrode 331 in an area where the bank 325 overlaps with the peripheral portion 320c of the insulating layer 320. For example, the step portion STP may be formed in a structure where the bank 323 is disposed to be spaced apart from at least one inclined portion 320b of the insulating layer 320 by a certain distance at the peripheral portion 320c of the insulating layer 320.

As the step portion STP is disposed at the peripheral portion 320c of the insulating layer 320, a distance between the bank 325 and a first portion 331a of the first electrode 331 increases, and thereby, even when outgas is emitted from the bank 325, a traveling distance of the outgas can increase.

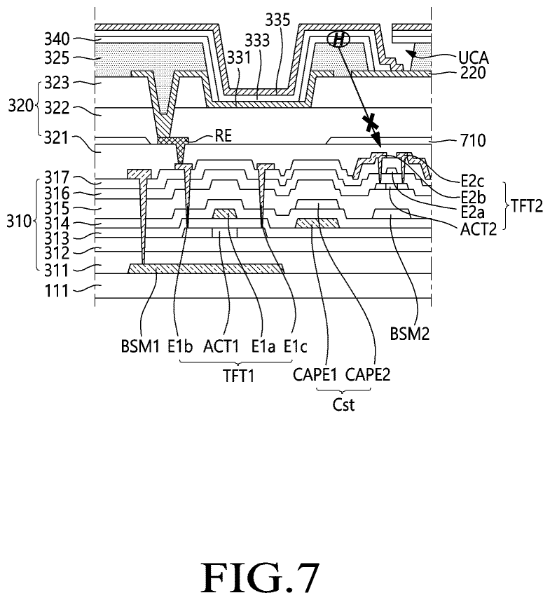

FIG. 7 is another example cross-sectional view taken along line I-I′ of FIG. 3 in the display panel 110 according to embodiments of the present disclosure. In discussions that follow for the configuration of FIG. 7, discussions for features and configurations equal, substantially equal, or similar to the features and configurations described with reference to FIGS. 1 to 6 are omitted or briefly described for simplicity.

Referring to FIG. 7, in one or more example embodiments, the display panel 110 may include a substrate 111, and a TFT array substrate 310, an insulating layer 320, a bank 325, a first electrode 331, an intermediate layer 333, a second electrode 335, and a protection layer 340, which are disposed on the substrate 111.

The TFT array substrate 310 may include transistors (TFT1 and TFT2). The transistors (TFT1 and TFT2) may include active layers (ACT1 and ACT2) including an oxide semiconductor. When the active layers (ACT1 and ACT2) include an oxide semiconductor, a conductivity-enabled phenomenon may occur by hydrogen in the active layers (ACT1 and ACT2).

The protection layer 340 may include a transparent inorganic insulating material. The protection layer 340 may be in the form of a single layer of silicon nitride (SiNx), silicon oxide (SiOx), or silicon oxynitride (SiOxNy), or a multilayer thereof. For example, when the protection layer 340 includes a nitride such as silicon nitride (SiNx) or silicon oxynitride (SiOxNy), hydrogen may remain in the process of depositing the protection layer 340. In this situation, the active layers (ACT1 and ACT2) may be conductivity-enabled by the hydrogen remaining in the protection layer 340.

Accordingly, a hydrogen capture layer 710 for preventing or reducing the movement of hydrogen may be disposed between the protection layer 340 and the active layers (ACT1 and ACT2).

The hydrogen capture layer 710 may be disposed on a first planarization layer 321. The hydrogen capture layer 710 may be disposed in an area overlapping with at least one active layer (ACT1 and/or ACT2). For example, the hydrogen capture layer 710 may be disposed to overlap with an area where a metal layer is not disposed between the protection layer 340 and the at least one active layer (ACT1 and/or ACT2).

As the hydrogen capture layer 710 is disposed in an area overlapping with the at least one active layer (ACT1 and/or ACT2), hydrogen remaining in the protection layer 340 can be effectively captured, and thereby, hydrogen can be prevented from diffusing into the at least one active layer (ACT1 and/or ACT2).

The hydrogen capture layer 340 may include a hydrogen capture metal. For example, the hydrogen capture metal may be at least one of titanium (Ti), tantalum (Ta), zirconium (Zr), scandium (Sc), yttrium (Y), lutetium (Lu), hafnium (Hf), vanadium (V), niobium (Nb), cerium (Ce), calcium (Ca), magnesium (Mg), barium (Ba), lithium (Li), and strontium (Sr), but embodiments of the present disclosure are not limited thereto.

In one or more embodiments, source electrodes and drain electrodes of the transistors (TFT1 and TFT2) may be disposed to overlap with the hydrogen capture layer 710. For example, second source and drain electrodes (E2b and E2c) of a second transistor TFT2 may be disposed to overlap with the hydrogen capture layer 710. For example, the second source and drain electrodes (E2b and E2c) of the second transistor TFT2 may be disposed to cover a second active layer ACT2. As the second source and drain electrodes (E2b and E2c) are disposed to overlap with the hydrogen capture layer 710 and cover the active layer, the movement of hydrogen can be prevented or reduced. FIG. 7 illustrates a structure in which the second source and drain electrodes (E2b and E2c) of the second transistor TFT2 are disposed to cover the second active layer ACT2, but embodiments of the present disclosure are not limited thereto. For example, first source and drain electrodes (E1b and E1c) of a first transistor TFT1 may also be disposed to cover a first active layer ACT1.

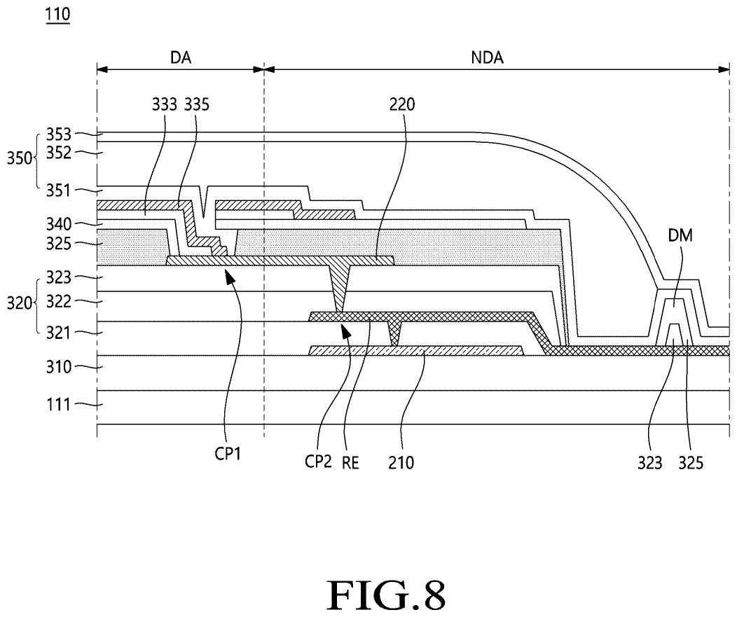

FIG. 8 is an example cross-sectional view taken along line II-II′ of FIG. 3 in the display panel 110 according to embodiments of the present disclosure. In discussions that follow for the configuration of FIG. 8, discussions for features and configurations equal, substantially equal, or similar to the features and configurations described with reference to FIGS. 1 to 7 are omitted or briefly described for simplicity.

In one or more example embodiments, FIG. 8 illustrates an example electrical connection structure of the auxiliary line 220 and the common voltage line 210 in an outer edge of the display panel 110.

Referring to FIG. 8, one or more first contacts CP1 may be formed in the display area DA. A second electrode 335 and an auxiliary line 220 may be electrically connected in a first contact CP1. The auxiliary line 220 may be electrically connected to the common voltage line 210 in the non-display area NDA. In order for the auxiliary line 220 to be electrically connected to the common voltage line 210, a second contact CP2 may be disposed under the auxiliary line 220. The second contact CP2 may be disposed in the non-display area NDA. The auxiliary line 220 may be electrically connected to the common voltage line 210 through the second contact CP2.

As the first contact CP1 electrically interconnecting the second electrode 335 and the auxiliary line 220 is disposed in the display area DA rather than the non-display area NDA, thereby, a bezel size of the display panel 110 can be reduced.

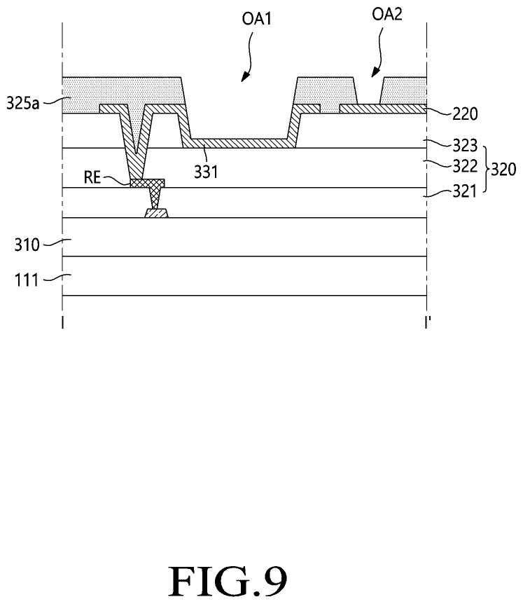

FIGS. 9 to 13 illustrate example processes of manufacturing the display panel 110 according to embodiments of the present disclosure. In discussions that follow for the configuration of FIGS. 9 to 13, discussions for features and configurations equal, substantially equal, or similar to the features and configurations described with reference to FIGS. 1 to 8 are omitted or briefly described for simplicity.

First, referring to FIG. 9, a substrate 111 and a TFT array substrate 310 may be formed sequentially. Next, an insulating layer 320 may be formed on the array substrate 310. The insulating layer 320 may include a depression 324 and at least one contact hole.

For example, as the insulating layer 320, a first insulating layer 321, a second insulating layer 322, and a third insulating layer 323 may be formed sequentially on the TFT array substrate 310. A contact holes for electrical connection with a source or drain electrode of a transistor may be formed in the first insulating layer 321. A contact hole for electrical connection with a relay electrode RE may be formed in the second insulating layer 322. A contact hole for electrical connection with a relay electrode RE and a depression in which a light emitting element is disposed may be formed in the third insulating layer 323.

Next, a first electrode 331 and an auxiliary line 220 may be formed by patterning on the insulating layer 320. The auxiliary line 220 may include the same material as a material included in the first electrode 331. The auxiliary line 220 may be formed in substantially the same layer as the first electrode 331. The first electrode 331 may be electrically connected to the relay electrode RE through the contact holes of the second insulating layer 322 and the third insulating layer 323. Accordingly, the first electrode 331 may be electrically connected to the transistor. The auxiliary line 220 may be formed to be spaced apart from the depression 324 and the first electrode 331.

Next, a bank 325a may be formed to cover the first electrode 331 and the auxiliary line 220. The bank 325a may be formed such that a first open area OA1 overlapping the depression 324 and a second open area OA2 exposing a portion of the auxiliary line 220 are formed by a patterning process. At least one portion of the first electrode 331 disposed on at least one inclined portion of the depression 324 and at least one inclined portion of the first open area OA1 of the bank 325a may be formed to have the same inclined surface. At this implementation, the bank 325a may include a black bank material.

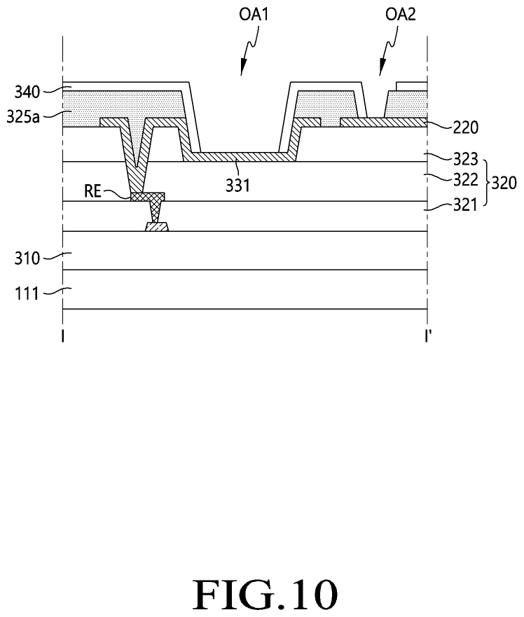

Next, referring to FIG. 10, a protection layer 340 may be formed on the bank 325a, the first electrode 331, and the auxiliary line 220. The protection layer 340 may include an inorganic insulating material. The protection layer 340 may be formed such that an upper surface of the first electrode 331 disposed in a flat portion of the depression 324 and an upper surface of the auxiliary line 220 disposed in the second open area OA2 are exposed by a patterning process. For example, the protection layer 340 may have a discontinuous structure in the area corresponding to the first open area OA1 and the second open area OA2. In this example, the protection layer 340 may be formed in the second open area OA2 such that the protection layer 340 extends along an inclined portion of a first side bank 325a and the protection layer 340 is disposed on a second side bank 325a without extending along an inclined portion of the second side bank 325a. For example, the inclined portion of the second side bank 325a may be exposed to the outside.

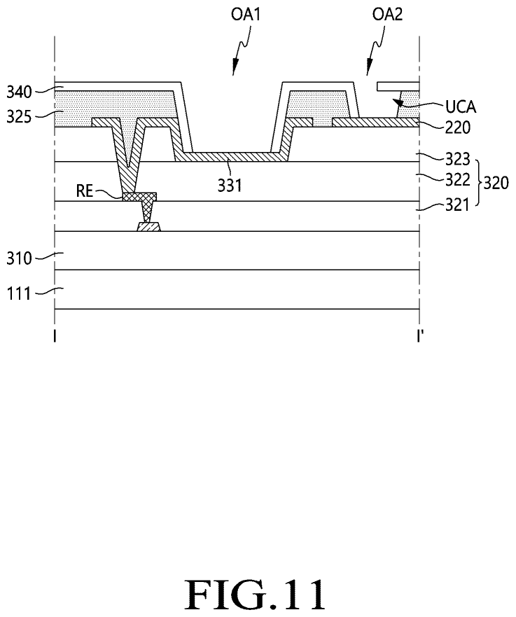

Next, referring to FIG. 11, the inclined portion of the second side bank 325a exposed to the outside may be additionally etched to complete the bank 325. In this implementation, the bank 325 may be formed by additional etching through an ashing or developing process using the protection layer 340 including an inorganic insulating material as a mask. According to this process, an undercut area UCA may be formed under the protection layer 340. The undercut area UCA may mean an area where the bank 325 is removed under the protection layer 340. In the undercut area UCA, the protection layer 340 may protrude beyond the bank 325. As the undercut area UCA is formed, a size of the second open area OA2 exposing the auxiliary line 220 may increase.

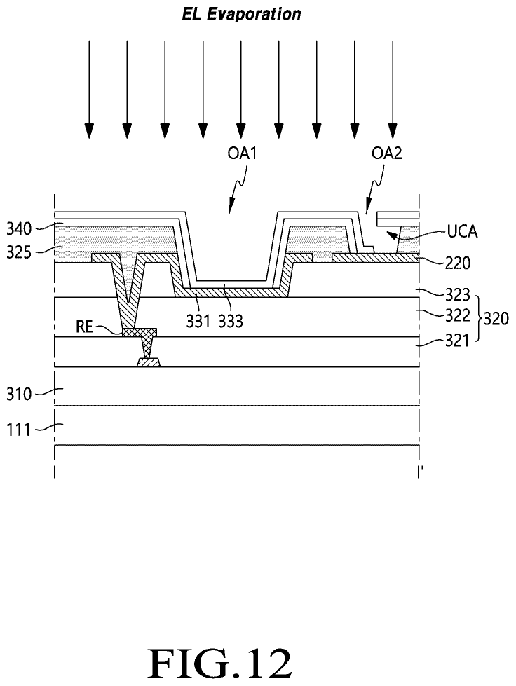

Next, referring to FIG. 12, an intermediate layer 333 may be formed on the protection layer 340, the first electrode 331, and the auxiliary line 220. The intermediate layer 333 may have a discontinuous structure in an area corresponding to the second open area OA2. The intermediate layer 333 may be formed through a deposition process having straightness, such as evaporation. For example, the intermediate layer 333 may be formed through a deposition process of evaporating an organic material. The intermediate layer 333 may be formed only on the protection layer 340, the first electrode 331, and the auxiliary line 220, and may not be formed in the undercut area UCA covered by the protection layer 340. For example, the intermediate layer 333 may not be formed on an inclined portion of the bank 323 located under the protection layer 340 with a protrusion in the second open area OA2 and on the auxiliary line 220. Since the intermediate layer 333 is formed to be disconnected in the second open area OA2, that is, has a discontinuous structure in the second open area OA2, the auxiliary line 220 may be exposed by the intermediate layer 333.

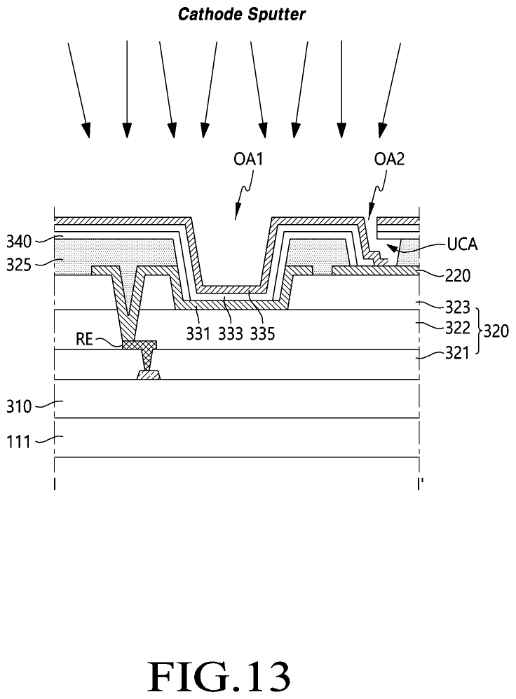

Referring to FIG. 13, a second electrode 335 may be formed on the intermediate layer 333. The second electrode 335 may have a discontinuous structure in the area corresponding to the second open area OA2. The second electrode 335 may be formed by a deposition process with an irregular direction such as sputtering. According to this process, the second electrode 335 may cover one end of the intermediate layer 333 within the second open area OA2 and may be deposited up to a portion of the auxiliary line 220. For example, the second electrode 335 may be formed up to the portion of the auxiliary line 220 overlapping with the undercut area UCA. For example, the second electrode 335 may be formed to extend to the portion of the auxiliary line 220 located under the protection layer 340 with the protrusion in the second open area OA2. Accordingly, the second electrode 335 may be easily electrically connected to the auxiliary line 220 in the second open area OA2, and the auxiliary line 220 may be electrically connected to a common voltage line 210 in an outer edge of the display area DA. Thereby, the display panel 110 can provide advantages of reducing the resistance of the second electrode 335 and improving the luminance uniformity.

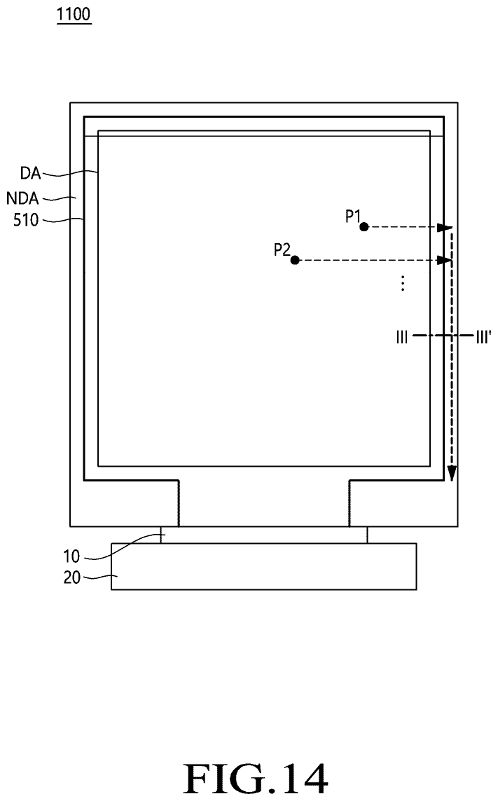

FIG. 14 is a plan view of an example display panel 1100 according to one embodiment. In discussions that follow for the configuration of FIG. 14, discussions for features and configurations equal, substantially equal, or similar to the features and configurations described with reference to FIGS. 1 to 13 are omitted or briefly described for simplicity.

Referring to FIG. 14, the display panel 1100 may be a structure where a common electrode CE extend to a non-display area NDA and is connected to a common voltage line 510 through a connection electrode in the non-display area NDA. In this structure, the common electrode CE may be in the form of a single layer commonly corresponding to a plurality of subpixels SP of the display panel 110. The common electrode CE may include a thin transparent conductive material to improve transmittance, and in this implementation, the common electrode CE may have a high surface resistance value. Accordingly, the common electrode CE may not have a constant voltage value within the whole surface. For example, a voltage difference may occur between a P1 area and a P2 area. A luminance difference between areas in the display area DA may occur due to this voltage drop (IR drop) phenomenon. For example, as the area of the display device 100 increases, the voltage drop phenomenon may become more severe.

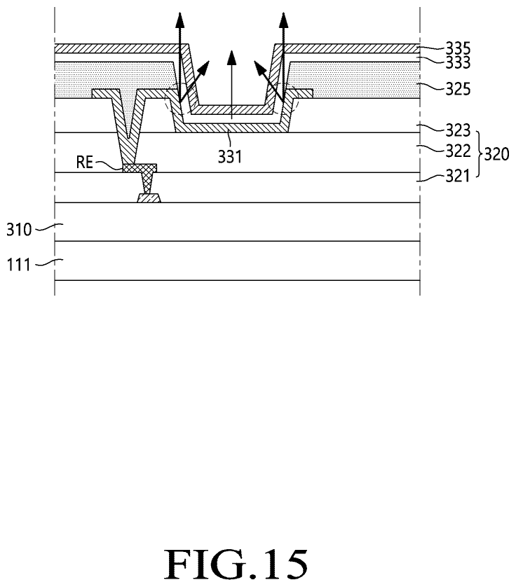

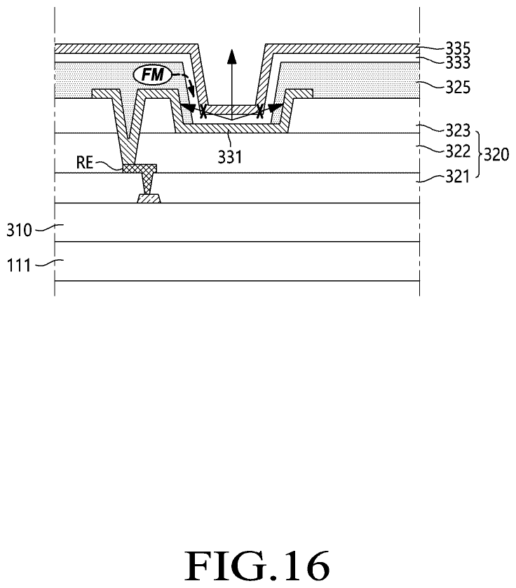

FIGS. 15 and 16 are example cross-sectional views of the display panel 1100 according to one embodiment. In discussions that follow for the configuration of FIGS. 15 and 16, discussions for features and configurations equal, substantially equal, or similar to the features and configurations described with reference to FIGS. 1 to 14 are omitted or briefly described for simplicity.

As illustrated in FIG. 15, the display panel 1100 may have an intermediate layer 333 disposed on a first electrode 331.

The intermediate layer 333 may be formed by a physical deposition method of an organic material on the first electrode 331 using an evaporation process. In this case, the intermediate layer 333 may have a thickness thinner in an area having a predetermined angle to the horizontal plane than in an area parallel to the horizontal plane. For example, a thickness of the intermediate layer 333 disposed in an area corresponding to an inclined portion of a depression 324 may be less than a thickness of the intermediate layer 333 disposed in an area corresponding to a flat portion of the depression 324. Accordingly, when a light emitting element ED is driven, current density is highest in an area where the intermediate layer 333 is formed at a relative thin thickness, for example, an area corresponding to the inclined portion of the depression 324, and a strong electric field may be applied in the area corresponding to the inclined portion of the depression 324. Therefore, emission characteristics of the light emitting element ED in the area corresponding to the inclined portion of the depression 324 and emission characteristics of the light emitting element ED in the area corresponding to the flat portion of the depression 324 may be different, and thereby, degradation of the element may occur.

As illustrated in FIG. 16, to prevent degradation of the element and different emission characteristics between areas, a bank 325 may be disposed to cover a first electrode 331 disposed in an inclined portion of a depression 324.

Referring to FIG. 16, the bank 325 may be disposed between the first electrode 331 and an intermediate layer 333 at the inclined portion of an insulating layer 320. When the bank 325 includes a transparent material, light traveling sideward after being emitted from the intermediate layer 331 may be reflected by the first electrode 331 located at the inclined portion and directed to exit display panel 1100. However, in this case, a reflection phenomenon due to external light may occur, and a problem may occur in which the reflection visibility is reduced. To address this problem, the bank 325 may include a black material, and thereby, the bank 325 can absorb external light.

However, as shown in FIG. 16, when the bank 325 including the black material is disposed between the first electrode 331 and the intermediate layer 333 and directly contacts the first electrode 331 and the intermediate layer 333, light traveling sideward from the intermediate layer 331 may be absorbed by the bank 325 and may not reach the first electrode 331 with reflective characteristics, and thus, may not exit the display panel 1100.

For example, when the bank 325 including the black material is disposed to directly contact the first electrode 331 and the intermediate layer 333, the bank 325 may be deteriorated in a high-temperature subsequent process, and outgas such as fume gas may be generated from the bank 325. In this situation, the outgas may contaminate the light emitting element ED and cause a pixel shrinkage phenomenon in which the size of a corresponding pixel decreases.

As described above, the display panel 110 according to one or more embodiments of the present disclosure may include the protection layer 340 disposed between the first electrode 331 and the intermediate layer 333 disposed on the inclined portion of the insulating layer 320 and between the bank 325 and the intermediate layer 333. When the protection layer 340 is disposed between the first electrode 331 and the intermediate layer 333 disposed on the inclined portion of the insulating layer 320, light traveling sideward from the intermediate layer 331 may be reflected by the first electrode 331 located on the inclined portion and directed to exit the display panel 110, and the phenomenon where degradation of the element and different emission characteristics between areas can occur may be prevented.

Further, when the protection layer 340 is disposed between the bank 325 including the black material and the intermediate layer 333, even when outgas is generated from the bank 325, the protection layer 340 can block the movement of the outgas, and thereby, prevent pixel shrinkage.

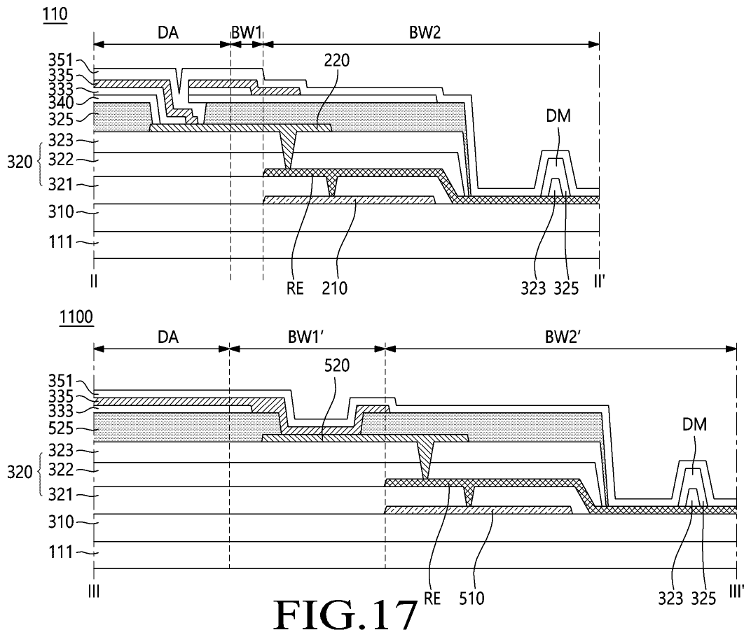

FIG. 17 illustrates an example cross-sectional view of the display panel 110 illustrated in FIG. 8 and an example cross-sectional view taken along line III-III′ in the display panel 1100 of FIG. 14 according to one embodiment. In discussions that follow for the configuration of FIG. 17, discussions for features and configurations equal, substantially equal, or similar to the features and configurations described with reference to FIGS. 1 to 16 are omitted or briefly described for simplicity.

FIG. 17 illustrates sizes of respective bezel areas of the display panel 110 according to one or more embodiments of the present disclosure and the display panel 1100.

Referring to FIG. 17, the display panel 110 may include a second electrode 335 and an auxiliary line 220 electrically connected in the display area DA, and the auxiliary line 220 and a common voltage line 210 may be electrically connected by a relay electrode RE in the non-display area NDA. In this configuration, the size of an area where the auxiliary line 220, the relay electrode RE, and the common voltage line 210 are electrically connected may be defined as BW2, and the size of an area between the display area DA and BW2 may be defined as BW1. In this case, the size of the bezel may be defined as BW1+BW2.

The display panel 1100 may include a second electrode 335 and a connection electrode 520 electrically connected in the non-display area NDA, and the connection electrode 520 and a common voltage line 210 may be electrically connected by a relay electrode RE. In this configuration, the size of an area where the connection electrode 520, the relay electrode RE, and the common voltage line 510 are electrically connected may be defined as BW2′, and the size of an area between the display area DA and BW2′ may be defined as BW1′. In this case, the size of the bezel may be defined as BW1′+BW2′.

Referring to FIG. 17, it can be seen that the sizes of BW2 and BW2′ are substantially the same, but the size of BW1 is smaller than the size of BW1′. This may mean that the size of the bezel of the display panel 110 according to one or more embodiments of the present disclosure is reduced by (BW1′−BW1) compared to the size of the bezel of the display panel 1100.

The examples, aspects, and embodiments for the display device 100 and the display panel 110 described herein may be described as follows.

According to the one or more example embodiments described herein, a display device can be provided that includes a substrate, an insulating layer disposed on the substrate and including a depression and a peripheral portion surrounding the depression, a first electrode disposed on the depression and the peripheral portion, an auxiliary line spaced apart from the first electrode and disposed on the peripheral portion, a bank covering at least a portion of the first electrode and the auxiliary line and disposed on the peripheral portion, a protection layer disposed on the first electrode and the bank, an intermediate layer disposed on the first electrode and the protection layer, and a second electrode electrically connected to the auxiliary line and disposed on the intermediate layer.

In one or more embodiments, the depression may include a flat portion and an inclined portion. In one or more embodiments, the first electrode may include a first portion corresponding to the flat portion and a second portion corresponding to the inclined portion. In one or more embodiments, the protection layer may include a first portion disposed on the second portion of the first electrode and at least one first side surface of the bank.

In one or more embodiments, the second portion of the first electrode may have a same inclined surface on a same plane as the at least one first side surface of the bank.

In one or more embodiments, the protection layer may include a second portion disposed on an upper surface of the bank, and a third portion disposed on a second side surface of the bank and contacting the auxiliary line.

In one or more embodiments, the intermediate layer may include a first portion disposed on the first portion of the first electrode and the first portion of the protection layer, a second portion disposed on the second portion of the protection layer, and a third portion disposed on the third portion of the protection layer and contacting the auxiliary line.

In one or more embodiments, the second electrode may include a first portion disposed on the first portion of the intermediate layer, a second portion disposed on the second portion of the intermediate layer, and a third portion disposed to cover the third portion of the intermediate layer and contact the auxiliary line.

In one or more embodiments, the bank may include an open area at least partially overlapping with the auxiliary line. In one or more embodiments, the second electrode may cover the intermediate layer in the open area and be electrically connected to the auxiliary line.

In one or more embodiments, the display device may include an undercut area overlapping with at least a portion of the open area. In one or more embodiments, the second electrode may be disposed to overlap with the undercut area in a plan view.

In one or more embodiments, the intermediate layer may be disposed not to overlap with the undercut area in the plan view.

In one or more embodiments, a side bank may be disposed to be spaced apart from the bank in a plan view. In one or more embodiments, the open area may be located between the bank and the side bank. In one or more embodiments, the protection layer may be disposed on the side bank and comprise a fourth portion protruding toward the open area.

In one or more embodiments, the intermediate layer may include a fourth portion disposed on the fourth portion of the protection layer. In one or more embodiments, the fourth portion of the intermediate layer may not overlap with the intermediate layer disposed on the auxiliary line in a plan view.

In one or more embodiments, the second electrode may include a fourth portion disposed on the fourth portion of the intermediate layer. In one or more embodiments, the fourth portion of the second electrode may overlap with the second electrode disposed on the auxiliary line in the plan view.

In one or more embodiments, the display device may include a step portion disposed on the peripheral portion and allowing the bank to expose a portion of the first electrode adjacent to the inclined portion.

In one or more embodiments, the bank may be a black bank. In one or more embodiments, the protection layer may be a transparent inorganic insulating layer.

In one or more embodiments, the auxiliary line and the first electrode may include the same material and be disposed on the same layer.

In one or more embodiments, the display device may include a common voltage line electrically connected to the auxiliary line.

In one or more embodiments, the display device may include a transistor including an active layer, and a hydrogen capture layer located between the protection layer and the transistor and overlapping with the active layer. In one or more embodiments, the active layer may be an oxide semiconductor.

In one or more embodiments, the transistor may include a gate electrode, a source electrode, and a drain electrode. In one or more embodiments, the source electrode and the drain electrode may overlap with the hydrogen capture layer.

In one or more embodiments, the substrate may include at least one subpixel, and the first electrode is disposed to correspond to the subpixel.

According to the one or more example embodiments described herein, a display device can be provided that includes a substrate including a display area and a non-display area surrounding the display area, an insulating layer located in the display area and including a depression and a peripheral portion, a first electrode disposed on the insulating layer, an auxiliary line spaced from the first electrode and disposed on the peripheral portion, a bank including a first open area corresponding to the depression and a second open area exposing a portion of the auxiliary line, a protection layer disposed on the first electrode located to correspond to an inclined portion of the depression and the bank, an undercut area overlapping with at least a portion of the second open area and disposed under the protection layer, an intermediate layer disposed on the first electrode and the protection layer, and a second electrode electrically connected to the auxiliary line in the undercut area and disposed on the intermediate layer.

In one or more embodiments, the undercut area may be disposed such that a hole is formed in a portion of a pattern in which the auxiliary line is disposed.

In one or more embodiments, the undercut area may be disposed in a straight line on a plane along a pattern in which the auxiliary line is disposed.

In one or more embodiments, the display device may include a common voltage line disposed in the non-display area. In one or more embodiments, the auxiliary line and the common voltage line may be electrically connected in the non-display area.

In one or more embodiments, the display device may include an encapsulation layer on the second electrode, a buffer layer on the encapsulation layer and a black matrix on the buffer layer, wherein the black matrix overlaps with at least a portion of the bank.

In one or more embodiments, the display area may include at least one light emitting area.

The display device 100 according to the embodiments of the present disclosure may be applied to mobile devices, video phones, smart watches, watch phones, wearable apparatuses, foldable apparatuses, rollable apparatuses, bendable apparatuses, flexible apparatuses, curved apparatuses, sliding apparatuses, variable apparatuses, electronic notebooks, e-books, portable multimedia players (PMP), personal digital assistants (PDA), MP3 players, mobile medical devices, desktop PCs, laptop PCs, netbook computers, workstations, navigation devices, car navigation devices, vehicle display apparatuses, vehicle apparatuses, theater apparatuses, theater display apparatuses, televisions, wallpaper devices, signage devices, game devices, notebook computers, monitors, cameras, camcorders, and home appliances, and the like.

The above description has been presented to enable any person skilled in the art to make and use the technical idea of the present disclosure and has been provided in the context of a particular application and its requirements. Various modifications, additions and substitutions to the described embodiments will be readily apparent to those skilled in the art, and the principles described herein may be applied to other embodiments and applications without departing from the scope of the present disclosure. The above description and the accompanying drawings provide examples of the technical features of the present disclosure for illustrative purposes only. That is, the disclosed embodiments are intended to illustrate the scope of the technical features of the present disclosure.

What is claimed is:

1. A display device comprising:
a substrate;
an insulating layer on the substrate, the insulating layer comprising a depression and a peripheral portion surrounding the depression;
a first electrode on the depression and the peripheral portion;
an auxiliary line spaced apart from the first electrode and on the peripheral portion,
a bank covering a respective portion of the first electrode and the auxiliary line and on the peripheral portion;
a protection layer on the first electrode and the bank;
an intermediate layer on the first electrode and the protection layer; and
a second electrode electrically connected to the auxiliary line and on the intermediate layer.

2. The display device of claim 1, wherein the depression comprises a flat portion and an inclined portion,
wherein the first electrode comprises a first portion corresponding to the flat portion and a second portion corresponding to the inclined portion, and
wherein the protection layer comprises a first portion on the second portion of the first electrode and at least one first side surface of the bank.

3. The display device of claim 2, wherein the second portion of the first electrode has a same inclined surface on a same plane as the at least one first side surface of the bank.

4. The display device of claim 2, wherein the protection layer comprises:
a second portion on an upper surface of the bank; and
a third portion on a second side surface of the bank, the third portion contacting the auxiliary line.

5. The display device of claim 4, wherein the intermediate layer comprises:
a first portion on the first portion of the first electrode and the first portion of the protection layer;
a second portion on the second portion of the protection layer; and
a third portion on the third portion of the protection layer, the third portion of the intermediate layer contacting the auxiliary line.

6. The display device of claim 5, wherein the second electrode comprises:
a first portion on the first portion of the intermediate layer;
a second portion on the second portion of the intermediate layer; and
a third portion that covers the third portion of the intermediate layer, the third portion of the second electrode contacting the auxiliary line.

7. The display device of claim 1, wherein the bank comprises an open area at least partially overlapping with the auxiliary line, and the second electrode covers the intermediate layer in the open area and is electrically connected to the auxiliary line.

8. The display device of claim 7, further comprising:
an undercut area overlapping with at least a portion of the open area,
wherein the second electrode overlaps with the undercut area in a plan view.

9. The display device of claim 8, wherein the intermediate layer is non-overlapping with the undercut area in the plan view.

10. The display device of claim 7, wherein a side bank is spaced apart from the bank in a plan view and the open area is located between the bank and the side bank, and
wherein the protection layer is on the side bank and comprises a fourth portion protruding toward the open area.

11. The display device of claim 10, wherein the intermediate layer comprises a fourth portion on the fourth portion of the protection layer, and the fourth portion of the intermediate layer is non-overlapping with the intermediate layer disposed on the auxiliary line in a plan view.

12. The display device of claim 11, wherein the second electrode comprises a fourth portion on the fourth portion of the intermediate layer, and the fourth portion of the second electrode overlaps with the second electrode disposed on the auxiliary line in the plan view.

13. The display device of claim 2, further comprising:
a step portion on the peripheral portion and allowing the bank to expose a portion of the first electrode adjacent to the inclined portion.

14. The display device of claim 1, wherein the bank is a black bank and the protection layer is a transparent inorganic insulating layer.

15. The display device of claim 1, wherein the auxiliary line and the first electrode comprise a same material and are on a same layer.

16. The display device of claim 1, further comprising:
a common voltage line electrically connected to the auxiliary line.

17. The display device of claim 1, further comprising:
a transistor including an active layer; and
a hydrogen capture layer between the protection layer and the transistor, the hydrogen capture layer overlapping with the active layer,
wherein the active layer comprises an oxide semiconductor.

18. The display device of claim 17, wherein the transistor comprises a gate electrode, a source electrode, and a drain electrode, and
wherein the source electrode and the drain electrode overlap with the hydrogen capture layer.

19. The display device of claim 17, wherein the substrate comprises at least one subpixel and the first electrode is disposed to correspond to the at least one subpixel.

20. A display device comprising:
a substrate comprising a display area and a non-display area surrounding the display area;
an insulating layer in the display area, the insulating layer comprising a depression and a peripheral portion;
a first electrode on the insulating layer;
an auxiliary line spaced apart from the first electrode and on the peripheral portion;
a bank comprising a first open area corresponding to the depression and a second open area exposing a portion of the auxiliary line;
a protection layer on the first electrode, the protection layer located to correspond to an inclined portion of the depression;
an undercut area overlapping with at least a portion of the second open area and under the protection layer;
an intermediate layer on the first electrode and the protection layer; and
a second electrode electrically connected to the auxiliary line in the undercut area, the second electrode on the intermediate layer.

21. The display device of claim 20, wherein the undercut area is disposed such that a hole is in a portion of a pattern in which the auxiliary line is disposed.

22. The display device of claim 20, wherein the undercut area is disposed in a straight line on a plane along a pattern in which the auxiliary line is disposed.

23. The display device of claim 20, further comprising:
a common voltage line in the non-display area,
wherein the auxiliary line and the common voltage line are electrically connected in the non-display area.

24. The display device of claim 20, further comprising:
an encapsulation layer on the second electrode;
a buffer layer on the encapsulation layer; and
a black matrix on the buffer layer, the black matrix overlapping with at least a portion of the bank.

25. The display device of claim 20, wherein the display area comprises at least one light emitting area.
